(19) United States
(12) Patent Application Publication
(10) Pub. No.: US 2022/0130721 A1
(43) Pub. Date: Apr. 28, 2022

(54) APPLICATION OF SELF-ASSEMBLED MONOLAYERS FOR IMPROVED VIA INTEGRATION

(71) Applicant: Intel Corporation, Santa Clara, CA (US)

(72) Inventors: Guillaume Bouche, Portland, OR (US); Shashi Vyas, Euclid, OH (US); Akm Shaestagir Chowdhury, Portland, OR (US); Andy Chih-Hung Wei, Yamhill, OR (US); Charles Henry Wallace, Portland, OR (US)

(73) Assignee: Intel Corporation, Santa Clara, CA (US)

(21) Appl. No.: 17/076,870

(22) Filed: Oct. 22, 2020

(51) Int. Cl. H01L 21/768; H01L 23/522

(52) U.S. Cl. CPC H01L 21/76844; H01L 23/5226; H01L 23/53295; H01L 21/76831; H01L 21/76832; H01L 21/76807

(57) ABSTRACT

Methods for fabricating an IC structure by applying self-assembled monolayers (SAMs) are disclosed. An example IC structure includes a stack of three metallization layers provided over a support structure, where the first metallization layer includes a bottom metal line, the third metallization layer includes a top metal line, and the second metallization layer includes a via coupled between the bottom metal line and the top metal line, where via's sidewalls are enclosed by a first dielectric material. Application of one or more SAMs results in at least a portion of the via's sidewalls being lined with a second dielectric material so that the second dielectric material is between the first dielectric material and an electrically conductive material of the via, where the dielectric constant of the second dielectric material is higher than that of the first dielectric material and lower than about 6.

### TECHNICAL FIELD

This disclosure relates generally to the field of semiconductor devices, and more specifically, to metallization stacks with integrated vias.

### BACKGROUND

For the past several decades, the scaling of features in integrated circuits has been a driving force behind an ever-growing semiconductor industry. Scaling to smaller and smaller features enables increased densities of functional units on the limited real estate of semiconductor chips. For example, shrinking transistor size allows for the incorporation of an increased number of memory or logic devices on a chip, lending to the fabrication of products with increased capacity. The drive for the ever-increasing capacity, however, is not without issue. The necessity to optimize the performance of each device and each interconnect becomes increasingly significant.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example, and not by way of limitation, in the figures of the accompanying drawings.

FIGS. 1A-1B provide a flow diagram of an example method of using self-assembled monolayers (SAMs) for integrating vias in metallization stacks, in accordance with some embodiments.

FIGS. 2A-2M illustrate top-down and cross-sectional side views at various stages in the manufacture of an example integrated circuit (IC) structure according to the method of FIGS. 1A-1B, in accordance with some embodiments.

FIGS. 3A and 3B are top views of, respectively, a wafer and dies that may include one or more metallization stacks where SAMs were applied for improved via integration, in accordance with various embodiments.

FIG. 4 is a cross-sectional side view of an IC package that may include one or more metallization stacks where SAMs were applied for improved via integration, in accordance with various embodiments.

FIG. 5 is a cross-sectional side view of an IC device assembly that may include one or more metallization stacks where SAMs were applied for improved via integration, in accordance with various embodiments.

FIG. 6 is a block diagram of an example computing device that may include one or more metallization stacks where SAMs were applied for improved via integration, in accordance with various embodiments.

### DETAILED DESCRIPTION

### Overview

The systems, methods and devices of this disclosure each have several innovative aspects, no single one of which is solely responsible for all desirable attributes disclosed herein. Details of one or more implementations of the subject matter described in this specification are set forth in the description below and the accompanying drawings.

For purposes of illustrating metallization stacks where SAMs were applied for improved via integration in the back-end-of-line (BEOL) as described herein it might be useful to first understand phenomena that may come into play during IC fabrication. The following foundational information may be viewed as a basis from which the present disclosure may be properly explained. Such information is offered for purposes of explanation only and, accordingly, should not be construed in any way to limit the broad scope of the present disclosure and its potential applications.

ICs commonly include electrically conductive microelectronic structures, known in the art as interconnects, to provide electrical connectivity between various components. In this context, the term “metallization stack” may be used to describe a stacked series of layers of electrically conductive wires (sometimes referred to as “metal lines”) which are electrically insulated from one another except for when/where they may need to be electrically connected. In a typical metallization stack, electrical connections between metal lines of different layers of a metallization stack are realized by means of vias filled with one or more electrically conductive materials, extending in a direction substantially perpendicular to the planes of the metal lines (i.e., extending in a vertical direction if the plane of the metal lines is considered to be a horizontal plane). Such vias are, therefore, integrated within the metallization stacks.

In the past, the sizes and the spacing of interconnects such as metal lines and vias have progressively decreased, and it is expected that in the future the sizes and the spacing of the interconnects will continue to progressively decrease, for at least some types of ICs (e.g., advanced microprocessors, chipset components, graphics chips, etc.). One measure of a size of a metal line is the critical dimension of the line width. One measure of the spacing of the metal lines is the line pitch, representing the center-to-center distance between the closest adjacent metal lines of a given layer of a metallization stack.

Smaller and smaller sizes and spacing of interconnects demands that performance of every interconnect is optimized. Resistance (R) and capacitance (C) provide some measures of performance optimization of vias integrated in metallization stacks. In general, it is desirable to decrease all resistances and capacitances associated with vias. In order to realize a more favorable capacitance, it is preferable that a via is surrounded by a low-k dielectric material. In order to realize a more favorable resistance, it is preferable that a via is formed of a barrierless material and that there is no barrier material at the top of the via at the junction to the metal line above.

However, optimizing via integration in terms of resistance and capacitance (RC) characteristics is not an easy task. For example, one challenge with surrounding vias by low-k dielectric materials is that such materials are difficult to integrate due to their porosity, lack of mechanical strength, and their tendency to lose integrity at their surface with etching and cleaning processes often used in semiconductor manufacturing. For similar reasons, usage of SAMs on the surface of low-k dielectric materials has proved challenging. Furthermore, via bottom-up selective growth is challenging for a via in a low-k dielectric material.

Disclosed herein are methods for fabricating an IC structure, e.g., for fabricating a metallization stack portion of an IC structure, by applying SAMs for improved via integration, as well as related semiconductor devices. An example IC structure includes a stack of a first, a second, and a third metallization layers provided over a support structure (e.g., a substrate, a wafer, or a chip), where the first metallization layer includes a bottom metal line, the third metallization layer includes a top metal line, the second metallization layer is between the first and the third metallization layers and includes a via having one end coupled to the bottom metal line and another end coupled to the top metal line (i.e., the via is coupled between the bottom metal line and the top metal line) and having sidewalls enclosed by a first dielectric material. Application of one or more SAMs results in at least a portion of the sidewalls of the via being lined with a second dielectric material so that the second dielectric material is between the first dielectric material and an electrically conductive material of the via, where the dielectric constant of the second dielectric material is higher than that of the first dielectric material and lower than about 6. Via integration is improved in such IC structures because the vias may be surrounded by low-k dielectric materials while eliminating (or at least reducing) the need for barrier materials at the sidewalls, bottoms, or tops of the vias, which is expected to lead to reducing the RC delays associated with via integration and increasing reliability in the final IC structures.

As used herein, the term “bottom metal line” refers to any electrically conductive structure/line that is provided in a layer of a metallization stack that is closer to the support structure than another layer of the metallization stack, while the term “top metal line” refers to any electrically conductive structure/line that is provided in the layer of the metallization stack that is above the layer of the bottom metal lines. In other words, the bottom metal lines are provided in a layer of the metallization stack that is between the support structure and the layer in which the top metal lines are provided. In various embodiments, such bottom and top metal lines may include electrically conductive structures other than lines/trenches (e.g., at least a portion of the bottom metal line may be a gate contact), and/or may be formed, or include, electrically conductive materials other than metals.

IC structures as described herein, in particular metallization stacks where SAMs were applied for improved via integration as described herein, may be used for providing electrical connectivity to one or more components associated with an IC or/and between various such components. In various embodiments, components associated with an IC include, for example, transistors, diodes, power sources, resistors, capacitors, inductors, sensors, transceivers, receivers, antennas, etc. Components associated with an IC may include those that are mounted on IC or those connected to an IC. The IC may be either analog or digital and may be used in a number of applications, such as microprocessors, optoelectronics, logic blocks, audio amplifiers, etc., depending on the components associated with the IC. The IC may be employed as part of a chipset for executing one or more related functions in a computer.

For purposes of explanation, specific numbers, materials and configurations are set forth in order to provide a thorough understanding of the illustrative implementations. However, it will be apparent to one skilled in the art that the present disclosure may be practiced without the specific details or/and that the present disclosure may be practiced with only some of the described aspects. In other instances, well-known features are omitted or simplified in order not to obscure the illustrative implementations.

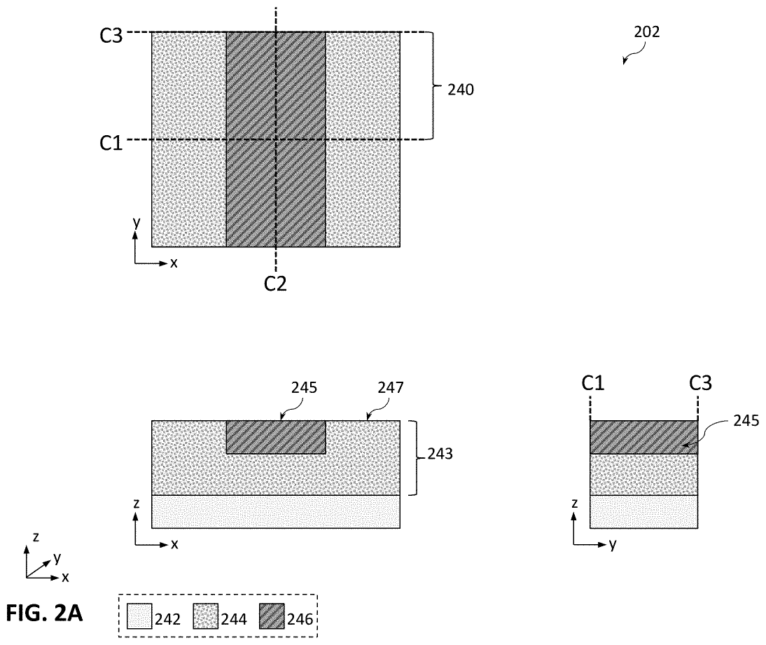

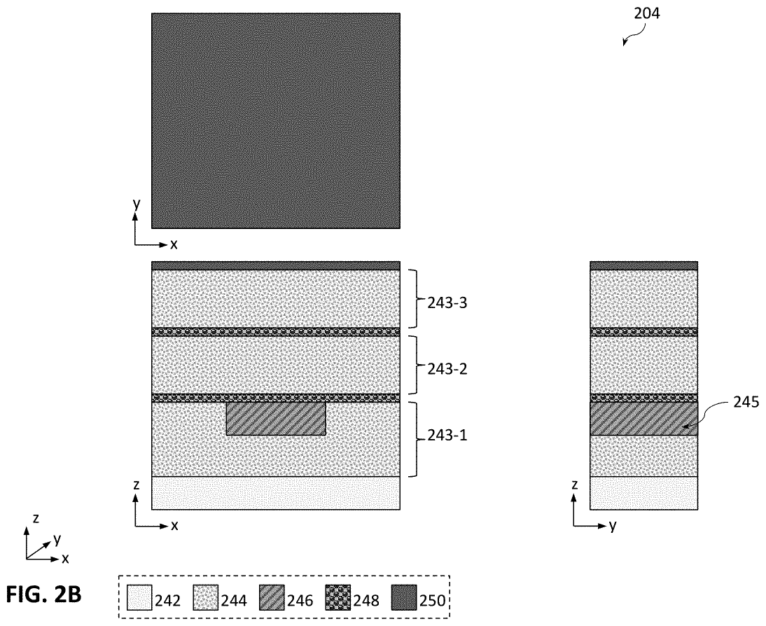

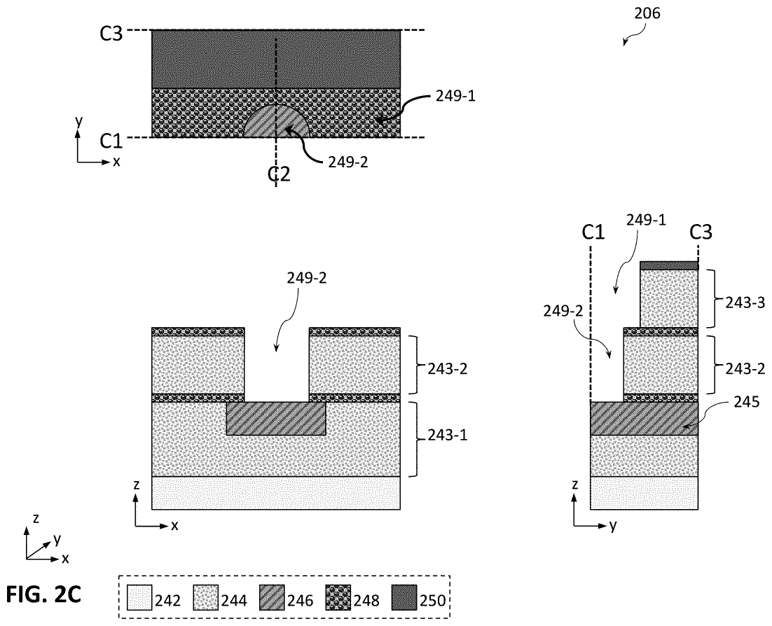

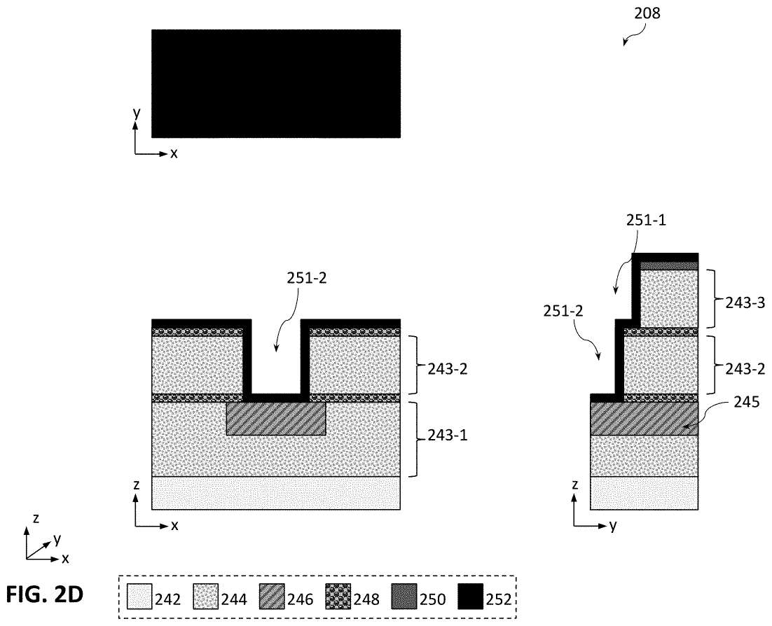

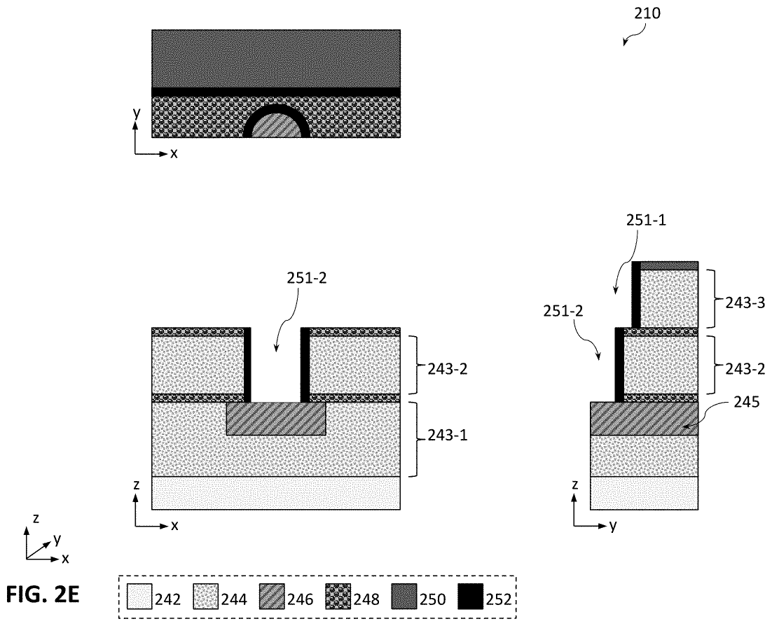

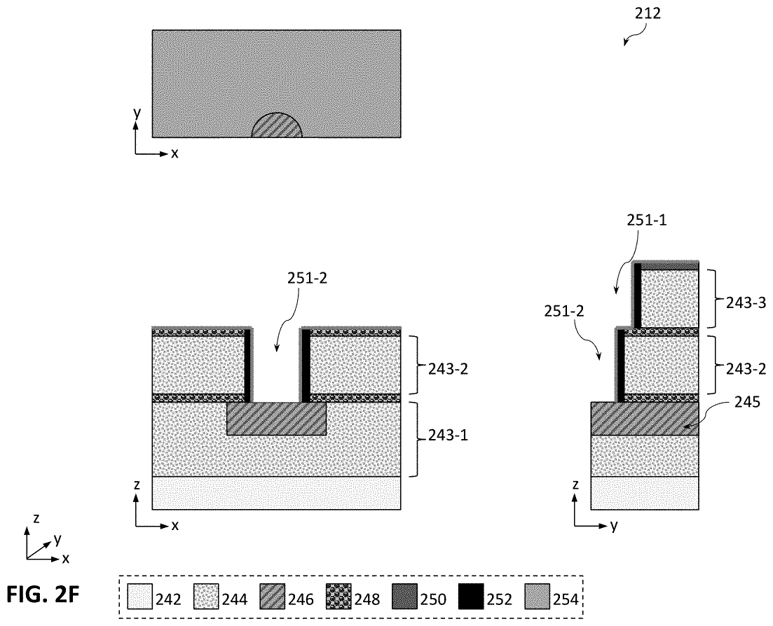

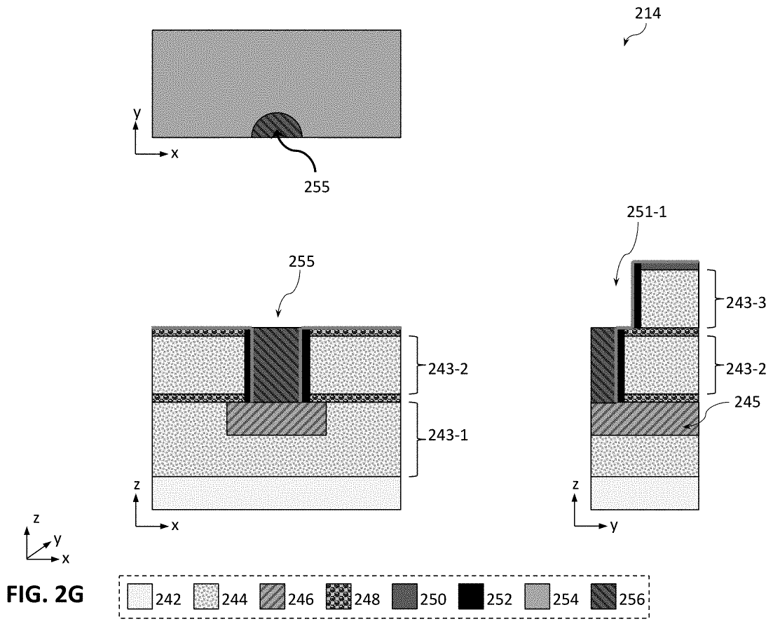

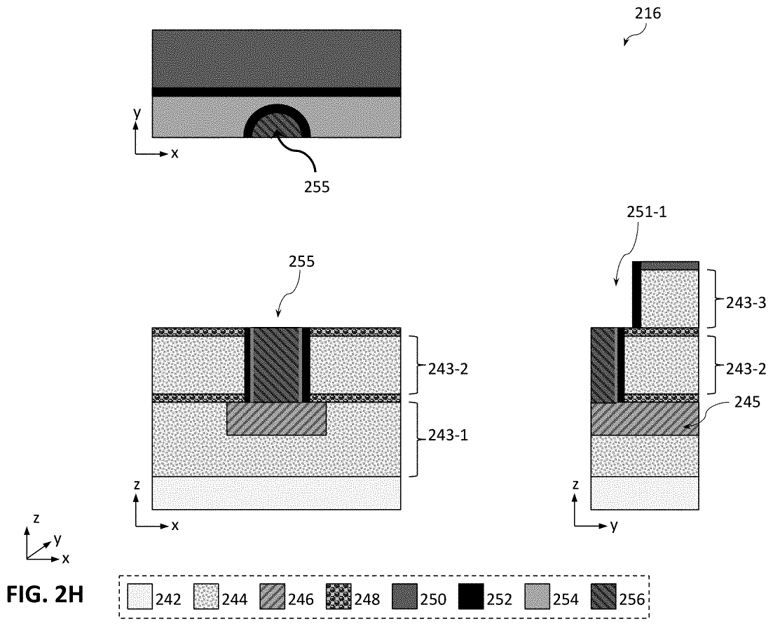

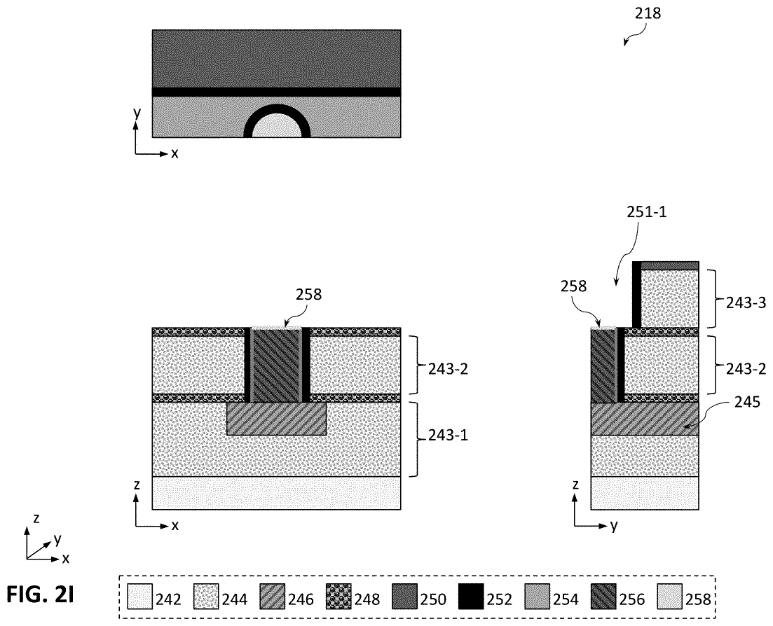

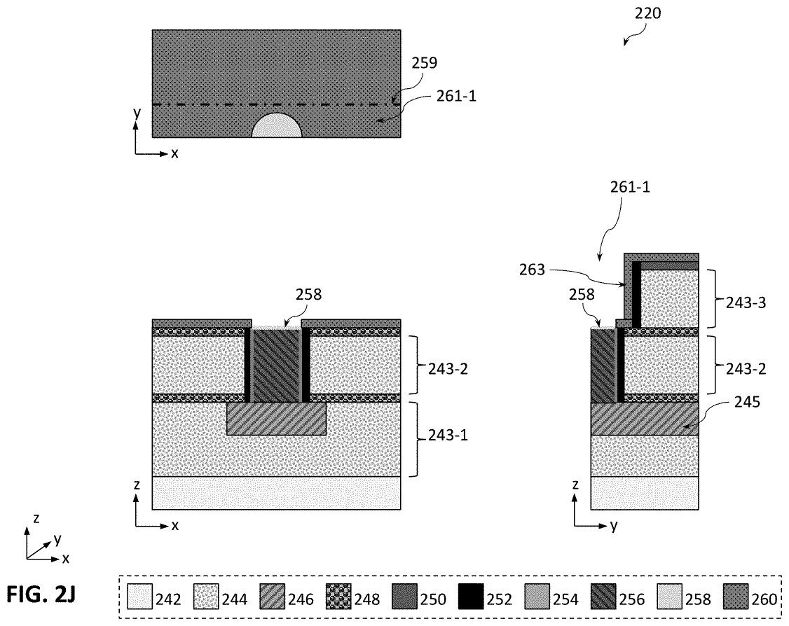

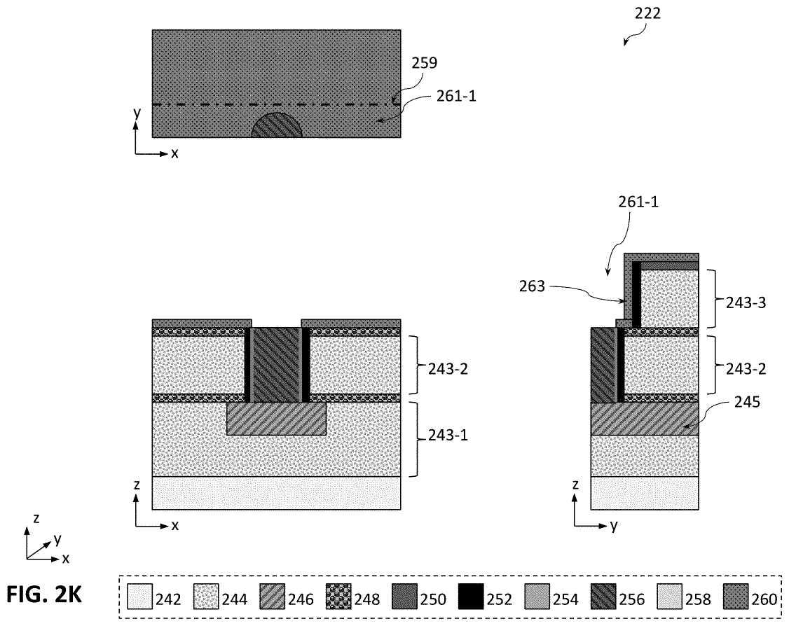

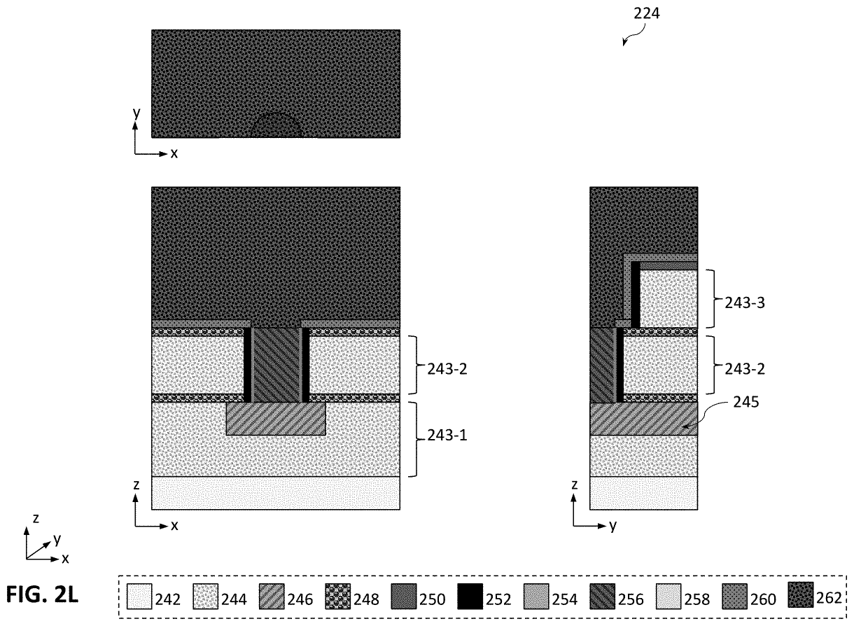

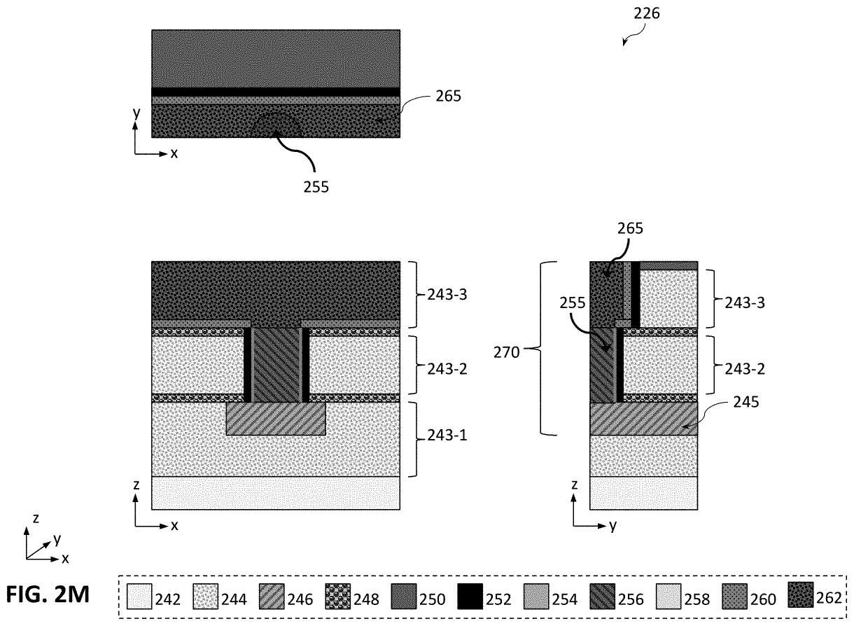

Further, references are made to the accompanying drawings that form a part hereof, and in which is shown, by way of illustration, embodiments that may be practiced. It is to be understood that other embodiments may be utilized, and structural or logical changes may be made without departing from the scope of the present disclosure. Therefore, the following detailed description is not to be taken in a limiting sense. For convenience, if a collection of drawings designated with different letters are present, e.g., FIGS. 2A-2M, such a collection may be referred to herein without the letters, e.g., as “FIG. 2.”

In the drawings, some schematic illustrations of example structures of various devices and assemblies described herein may be shown with precise right angles and straight lines, this is simply for ease of illustration, and embodiments of these assemblies may be curved, rounded, or otherwise irregularly shaped as dictated by, and sometimes inevitable due to, the manufacturing processes used to fabricate semiconductor device assemblies. Therefore, it is to be understood that such schematic illustrations may not reflect real-life process limitations which may cause the features to not look so “ideal” when any of the structures described herein are examined using e.g., scanning electron microscopy (SEM) images or transmission electron microscope (TEM) images. In such images of real structures, possible processing defects could also be visible, e.g., not-perfectly straight edges of materials, tapered vias or other openings, inadvertent rounding of corners or variations in thicknesses of different material layers, occasional screw, edge, or combination dislocations within the crystalline region, and/or occasional dislocation defects of single atoms or clusters of atoms. There may be other defects not listed here but that are common within the field of device fabrication. Inspection of layout and mask data and reverse engineering of parts of a device to reconstruct the circuit using e.g., optical microscopy, TEM, or SEM, and/or inspection of a cross-section of a device to detect the shape and the location of various device elements described herein using e.g., Physical Failure Analysis (PFA) would allow determination of presence of one or more metallization stacks where SAMs were applied for improved via integration as described herein.

Various operations may be described as multiple discrete actions or operations in turn, in a manner that is most helpful in understanding the claimed subject matter. However, the order of description should not be construed as to imply that these operations are necessarily order dependent. These operations may not be performed in the order of presentation. Operations described may be performed in a different order from the described embodiment. Various additional operations may be performed, and/or described operations may be omitted in additional embodiments.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C). The term “between,” when used with reference to measurement ranges, is inclusive of the ends of the measurement ranges.

The description uses the phrases “in an embodiment” or “in embodiments,” which may each refer to one or more of the same or different embodiments. The terms “comprising,” “including,” “having,” and the like, as used with respect to embodiments of the present disclosure, are synonymous. The disclosure may use perspective-based descriptions such as “above,” “below,” “top,” “bottom,” and “side”; such descriptions are used to facilitate the discussion and are not intended to restrict the application of disclosed embodiments. The accompanying drawings are not necessarily drawn to scale. Unless otherwise specified, the use of the ordinal adjectives “first,” “second,” and “third,” etc., to describe a common object, merely indicate that different instances of like objects are being referred to, and are not intended to imply that the objects so described must be in a given sequence, either temporally, spatially, in ranking or in any other manner.

In the following detailed description, various aspects of the illustrative implementations will be described using terms commonly employed by those skilled in the art to convey the substance of their work to others skilled in the art. For example, if used, the terms “oxide,” “carbide,” “nitride,” etc. refer to compounds containing, respectively, oxygen, carbon, nitrogen, etc., the term “high-k dielectric” refers to a material having a higher dielectric constant than silicon oxide, while the term “low-k dielectric” refers to a material having a lower dielectric constant than silicon oxide. In another example, a term “interconnect” is used to describe any element formed of an electrically conductive material for providing electrical connectivity to one or more components associated with an IC or/and between various such components. In general, the “interconnect” may refer to both trench contacts (also sometimes referred to as “lines”) and vias. In general, a term “trench contact” is used to describe an electrically conductive element isolated by a dielectric material typically comprising an interlayer low-k dielectric that is provided within the plane of an IC chip. Such trench contacts are typically stacked into several levels, or several layers of metallization stacks. On the other hand, the term “via” is used to describe an electrically conductive element that interconnects two or more trench contacts of different levels. To that end, integrated vias as described herein may be provided substantially perpendicularly to the plane of an IC chip. Any of these vias may interconnect two trench contacts in adjacent levels or two trench contacts in not adjacent levels. A term “metallization stack” refers to a stack of one or more interconnects for providing connectivity to different circuit components of an IC chip. The terms “substantially,” “close,” “approximately,” “near,” and “about,” generally refer to being within +/−20% of a target value based on the context of a particular value as described herein or as known in the art.

### Example Method of Fabricating an IC Structure Using SAMs

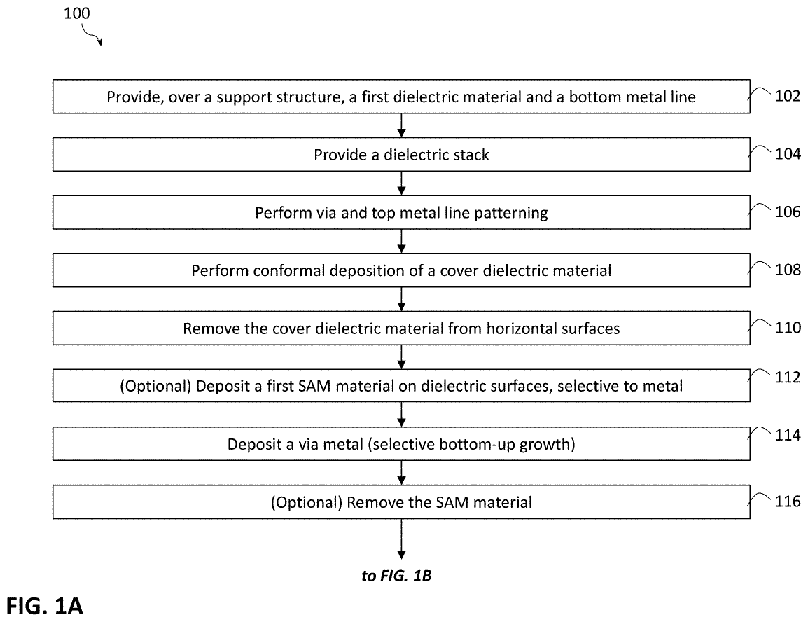

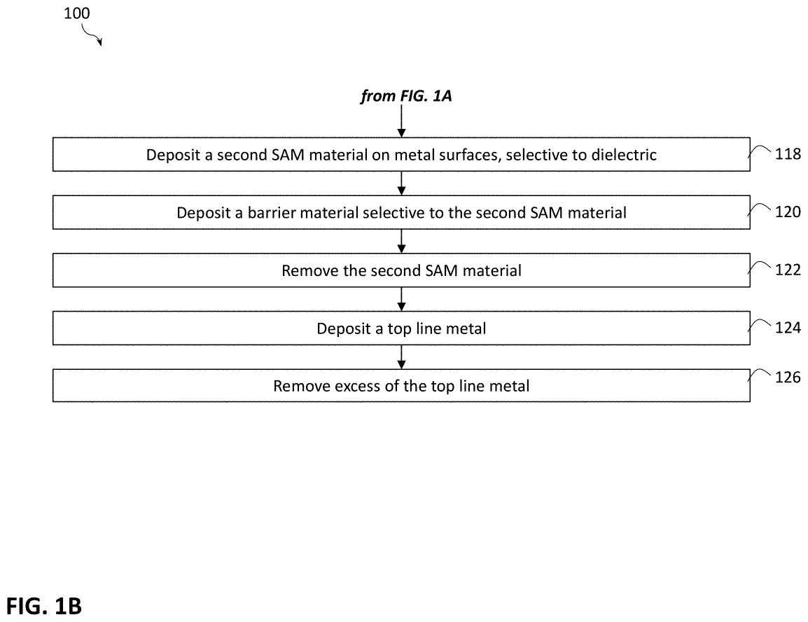

FIGS. 1A-1B provide a flow diagram of an example method 100 of using SAMs for integrating vias in metallization stacks, in accordance with some embodiments.

Although the operations of the method 100 are illustrated once each and in a particular order, the operations may be performed in any suitable order and repeated as desired. For example, one or more operations may be performed in parallel to manufacture, substantially simultaneously, multiple metallization stacks where SAMs were applied for improved via integration as described herein. In another example, the operations may be performed in a different order to reflect the structure of a particular device assembly in which one or more metallization stacks where SAMs were applied for improved via integration as described herein will be included.

In addition, the example manufacturing method 100 may include other operations not specifically shown in FIGS. 1A-1B, such as various cleaning or planarization operations as known in the art. For example, in some embodiments, a support structure, as well as layers of various other materials subsequently deposited thereon, may be cleaned prior to, after, or during any of the processes of the method 100 described herein, e.g., to remove oxides, surface-bound organic and metallic contaminants, as well as subsurface contamination. In some embodiments, cleaning may be carried out using e.g., a chemical solutions (such as peroxide), and/or with ultraviolet (UV) radiation combined with ozone, and/or oxidizing the surface (e.g., using thermal oxidation) then removing the oxide (e.g., using hydrofluoric acid (HF)). In another example, the arrangements/devices described herein may be planarized prior to, after, or during any of the processes of the method 100 described herein, e.g., to remove overburden or excess materials. In some embodiments, planarization may be carried out using either wet or dry planarization processes, e.g., planarization be a chemical mechanical planarization (CMP), which may be understood as a process that utilizes a polishing surface, an abrasive and a slurry to remove the overburden and planarize the surface.

Various operations of the method 100 may be illustrated with reference to the example embodiments shown in FIGS. 2A-2M, illustrating top-down and cross-sectional side views for various stages in the manufacture of an example IC structure that includes a metallization stack where SAMs were applied for improved via integration, in accordance with some embodiments. In particular, the top illustration of each of FIGS. 2A-2M shows a top-down view of the IC structure (i.e., the view of an x-y plane of a reference coordinate system x-y-z shown at the bottom left corner of each of FIGS. 2A-2M), the bottom left illustration of each of FIGS. 2A-2M shows a cross-section side view of the IC structure along a plane C1 (i.e., the cross-section taken along the x-z plane of the reference coordinate system), while the bottom right illustration of each of FIGS. 2A-2M shows a cross-section side view of the IC structure along a plane C2, between planes C1 and C3 (i.e., the cross-section taken along the y-z plane of the reference coordinate system, between the planes C1 and C3). The planes C1, C2, and C3 are illustrated with dashed lines in FIG. 2A only, in order to not clutter the other drawings.

A number of elements referred to in the description of FIGS. 2A-2M with reference numerals are illustrated in these figures with different patterns, with a legend showing the correspondence between the reference numerals and patterns being provided at the bottom of each drawing page containing FIGS. 2A-2M. For example, the legend illustrates that FIGS. 2A-2M use different patterns to show a support structure 242, a first dielectric material 244, an electrically conductive material 246 of a bottom metal line, etc. Furthermore, although a certain number of a given element may be illustrated in some of FIGS. 2A-2M (e.g., one bottom metal line, one top metal line, and one via integrated between the bottom metal line and the top metal line), this is simply for ease of illustration, and more, or less, than that number may be included in an IC structure fabricated according to the method 100. Still further, various views shown in FIGS. 2A-2M are intended to show relative arrangements of various elements therein. In other embodiments, various IC structures with a metallization stack where SAMs were applied for improved via integration, or portions thereof, may include other elements or components that are not illustrated (e.g., transistor portions, various components that may be in electrical contact with any of the bottom metal line, the top metal line, and the via in between, etc.).

Turning to FIG. 1A, the method 100 may begin with a process 102 that includes providing, over a support structure, a layer of a first dielectric material and a bottom metal line in the first dielectric material. An IC structure 202, depicted in FIG. 2A, illustrates an example result of the process 102. As shown in FIG. 2A, the IC structure 202 may include a support structure 242 with a layer 243 of a first dielectric material 244 provided thereon and a bottom metal line 245 of a first electrically conductive material 246. FIG. 2A illustrates that, in some embodiments, the top of the bottom metal line 245 may be aligned with the top 247 of the first dielectric material 244 (i.e., the bottom metal line 245 may be provided in a trench within the first dielectric material 244). FIG. 2A also illustrates that, in some embodiments, a longitudinal axis of the bottom metal line 245, which is an axis extending in the direction of the y-axis in the x-y plane of the reference coordinate system shown in FIG. 2A, may be substantially parallel to the support structure 242 (i.e., the bottom metal line 247 may extend in a direction that is substantially parallel to the support structure 242).

In general, implementations of the disclosure may be formed or carried out on a substrate, such as a semiconductor substrate composed of semiconductor material systems including, for example, N-type or P-type materials systems. In one implementation, the semiconductor substrate may be a crystalline substrate formed using a bulk silicon or a silicon-on-insulator substructure. In other implementations, the semiconductor substrate may be formed using alternate materials, which may or may not be combined with silicon, that include but are not limited to germanium, indium antimonide, lead telluride, indium arsenide, indium phosphide, gallium arsenide, indium gallium arsenide, gallium antimonide, or other combinations of group III-V, group II-VI, or group IV materials. Although a few examples of materials from which the substrate may be formed are described here, any material that may serve as a foundation upon which an IC may be built falls within the spirit and scope of the present disclosure. In various embodiments, the support structure 242 may include any such substrate, possibly with some layers and/or devices already formed thereon, not specifically shown in the present figures, providing a suitable surface for forming metallization stacks where SAMs were applied for improved via integration in the BEOL.

The first dielectric material 244 may be provided over the support structure 242 using a technique such as spin-coating, dip-coating, atomic layer deposition (ALD), chemical vapor deposition (CVD), or physical vapor deposition (PVD) (e.g., evaporative deposition, magnetron sputtering, or e-beam deposition). In some embodiments, the first dielectric material 244 may be a low-k dielectric material. Examples of the low-k dielectric materials that may be used as the first dielectric material 244 include, but are not limited to, silicon dioxide, carbon-doped oxide, silicon nitride, fused silica glass (FSG), and organosilicates such as silsesquioxane, siloxane, and organosilicate glass. Other examples of low-k dielectric materials that may be used as the first dielectric material 244 include organic polymers such as polyimide, benzocyclobutene, polynorbornenes, perfluorocyclobutane, or polytetrafluoroethylene (PTFE). Still other examples of low-k dielectric materials that may be used as the first dielectric material 244 include silicon-based polymeric dielectrics such as hydrogen silsesquioxane (HSQ) and methylsilsesquioxane (MSQ). Other examples of low-k materials that may be used in the first dielectric material 244 include various porous dielectric materials, such as for example porous silicon dioxide or porous carbon-doped silicon dioxide, where voids or pores are created in a dielectric in order to reduce the overall dielectric constant of the material, since voids or pores can have a dielectric constant of nearly 1.

In various embodiments, the bottom metal line 245 may be formed using any suitable technique, such as photolithography, electron-beam lithography, single-Damascene or dual-Damascene techniques. The first electrically conductive material 246 may be formed in the process 102 using a deposition technique such as, but not limited to, ALD, CVD, PVD, plasma enhanced CVD (PECVD), or electroplating. In general, various electrically conductive materials described herein, e.g., the first electrically conductive material 246, may include one or more of any suitable electrically conductive materials (conductors). Such materials may include any suitable electrically conductive material, alloy, or a stack of multiple electrically conductive materials. In some embodiments, various electrically conductive materials described herein may include one or more metals or metal alloys, with metals such as copper, ruthenium, palladium, platinum, cobalt, nickel, molybdenum, hafnium, zirconium, titanium, tantalum, and aluminum. In some embodiments, various electrically conductive materials described herein may include one or more electrically conductive alloys, oxides (e.g., conductive metal oxides), carbides (e.g., hafnium carbide, zirconium carbide, titanium carbide, tantalum carbide, and aluminum carbide, tungsten, tungsten carbide), or nitrides (e.g. hafnium nitride, zirconium nitride, titanium nitride, tantalum nitride, and aluminum nitride) of one or more metals.

The method 100 may then include a process 104 that involves providing a dielectric stack of materials over the bottom metal line formed in the process 102. An IC structure 204, depicted in FIG. 2B, illustrates an example result of the process 104. As shown in FIG. 2B, the IC structure 204 may include an etch stop material 248 provided over the IC structure 202, and then a second layer 243-2 of a dielectric material (the layer 243 illustrated in FIG. 2A now becomes the first layer 243-1 in FIG. 2B and subsequent drawings because FIG. 2B and subsequent drawings illustrate more than one dielectric layers). In various embodiments, the etch stop material 248 may include materials such as aluminum nitride, aluminum oxide, silicon nitride, or silicon carbon nitride. In some embodiments, the second layer 243-2 may be another layer of the first dielectric material 244 as described above (as is illustrated in FIG. 2B), although in other embodiments the exact material composition of the dielectric materials of the first and second layers 243-1 and 243-2 may be different.

FIG. 2B also illustrates a third layer 243-3 of a dielectric material provided over the second layer 243-2. As shown in FIG. 2B, in some embodiments, the third layer 243-3 may be another layer of the first dielectric material 244 as described above, although the exact material composition of the dielectric materials of the first and third layers 243-1 and 243-3 may be different in different embodiments. Furthermore, in various embodiments, the material composition of the dielectric materials of the second and third layers 243-2 and 243-3 may be either substantially the same or different. FIG. 2B and the subsequent drawings illustrates that a thin layer of the etch stop material 248 may separate the second and third layers 243-2 and 243-3, although this layer is optional and may be omitted in other embodiments of the IC structures described herein, in which case the second and third layers 243-2 and 243-3 may be a single layer of one or more dielectric materials. Whether or not the etch stop material 248 is present between the second and third layers 243-2 and 243-3, the layers 243-1, 243-2, and 243-3 may also be referred to as, respectively, first, second, and third metallization layers of a metallization stack because these are the layers that will house, respectively, a bottom metal line, a via, and a top metal line of the final metallization stack of the IC structure.

FIG. 2B further illustrates a layer of a second dielectric material 250 provided over the third layer 243-3. The second dielectric material 250 may be a dielectric material having a higher dielectric constant than that of the first dielectric material 244. For example, the second dielectric material 250 may include materials such as silicon dioxide, carbon-doped silicon dioxide, silicon nitride, aluminum nitride, or aluminum oxide. In some embodiments, a thickness of the second dielectric material 250 (i.e., a dimensioned measured along the z-axis of the example coordinate system shown in FIG. 2) may be between about 2 and 40 nanometers, including all values and ranges therein, e.g., between about 2 and 20 nanometers or between about 5 and 15 nanometers.

Together, a layer of the etch stop material 248 provided between the first and second layers 243-1 and 243-2, the second and third layers 243-2 and 243-3, and a layer of the second dielectric material 250 form a dielectric stack provided in the process 104. In various embodiments, each of these layers may be deposited using techniques such as spin-coating, dip-coating, ALD, CVD, or PVD. In some embodiments, a thickness of the etch stop material 248 (i.e., a dimensioned measured along the z-axis of the example coordinate system shown in FIG. 2) between various dielectric layers may be between about 1 and 25 nanometers, including all values and ranges therein, e.g., between about 1 and 10 nanometers or between about 1 and 5 nanometers. On the other hand, thicknesses of each of the first, second, and third layers 243-1, 243-2, and 243-3 may be of any suitable values or ranges for housing, respectively, a bottom metal line, a via, and a top metal line of the final metallization stack.

The method 100 may then proceed with a process 106, which includes patterning the dielectric stack formed in the process 104 to create an opening for a top metal line and an opening for a via. An IC structure 206, depicted in FIG. 2C, illustrates an example result of the process 106. As shown in FIG. 2C, the IC structure 206 may include an opening 249-1 for the future top metal line, provided in the third layer 243-3, and an opening 249-2 for the future via, provided in the second layer 243-2. The process 106 may include patterning the third dielectric layer 243-3 to form the opening 249-1 for the future top metal line that extends in a direction that is substantially parallel to the support structure 242. FIG. 2C illustrates that the opening 249-1 extends in a direction substantially perpendicular to that in which the bottom metal line 245 extends, although in other embodiments their relative orientation with respect to one another may be different, as long as both extend in directions substantially parallel to the support structure 242. The process 106 may further include patterning the second dielectric layer 243-2, through the opening 249-1 formed in the third dielectric layer 243-3, to form the opening 249-2 for the future via in the second dielectric layer 243-2. The via opening 249-2 should be suitable for providing a conductive via to enable electrical coupling between the bottom metal line 245 and a top metal line to be formed in the top metal line opening 249-1. To that end, as shown in FIG. 2C, the via opening 249-2 may extend all the way to expose the first electrically conductive material 246 of the bottom metal line 245 at the bottom of the via opening 249-2.

In some embodiments, a width of the via opening 249-2 (i.e., a dimensioned measured along the x-axis of the example coordinate system shown in FIG. 2) may be between about 5 and 100 nanometers, including all values and ranges therein, e.g., between about 10 and 45 nanometers or between about 12 and 25 nanometers. Although FIG. 2C and subsequent drawings illustrate the via opening 249-2 as having a substantially circular cross-section (i.e., a section of the via opening 249-2 in an x-y plane), in other embodiments that cross-section may be of other geometries, e.g., substantially square, rectangular, or of any polygonal shape, possibly with rounded corners.

In various embodiments, the top metal line opening 249-1 and the via opening 249-2 may be formed in the process 106 using any suitable etching technique (e.g., a dry etch, such as e.g., radio frequency (RF) reactive ion etch (RIE) or inductively coupled plasma (ICP) RIE) in combination with lithography (e.g., photolithography or electron-beam lithography) to define the locations and the sizes of these openings. In some embodiments, the etches performed in the process 106 to form the top metal line opening 249-1 and the via opening 249-2 may include an anisotropic etch, using etchants in a form of e.g., chemically active ionized gas (i.e., plasma) using e.g., bromine (Br) and chloride (CI) based chemistries. In some embodiments, during the etches of the process 106, the IC structure may be heated to elevated temperatures, e.g., to temperatures between about room temperature and 200 degrees Celsius, including all values and ranges therein, to promote that byproducts of the etch are made sufficiently volatile to be removed from the surface.

Patterning the top metal line opening 249-1 and the via opening 249-2 in the process 106 is likely to damage the dielectric material(s) in which these openings are formed, resulting in the sidewalls of the top metal line opening 249-1 and the via opening 249-2 having damaged surfaces. Such surfaces are not suitable for depositing SAMs and, more generally, may be detrimental for the overall functionality of the final IC structure. Therefore, the method 100 may then proceed with a process 108, in which a cover dielectric material is conformally deposited over and in the openings formed in the process 106, covering the damaged surfaces. An IC structure 208, depicted in FIG. 2D, illustrates an example result of the process 108. As shown in FIG. 2D, the IC structure 208 may include a cover dielectric material 252 that has been conformally deposited over and in the top metal line opening 249-1 and the via opening 249-2 formed in the process 106. As a result, these openings become narrower, shown in FIG. 2D as an opening 251-1 that is the top metal line opening 249-1 lined with the cover dielectric material 252, and an opening 251-2 that is the via opening 249-2 lined with the cover dielectric material 252. As shown in FIG. 2D, the cover dielectric material 252 may line sidewalls and bottoms of the top metal line opening 249-1 and the via opening 249-2, where, as used herein, the term “sidewall” refers to surfaces that are substantially perpendicular to the support structure 242. Any suitable conformal deposition technique may be used to provide the cover dielectric material 252 in the process 108, such as ALD or CVD.

In some embodiments, a thickness of the cover dielectric material 252 at the sidewalls of the via opening 249-2 (i.e., a dimensioned measured along the x-axis of the example coordinate system shown in FIG. 2) may be between about 1 and 20 nanometers, including all values and ranges therein, e.g., between about 2 and 10 nanometers or between about 3 and 8 nanometers. This may also be the thickness of the cover dielectric material 252 at other surfaces of the IC structure 208.

The cover dielectric material 252 may be any dielectric material having a higher dielectric constant than that of the dielectric material of the second dielectric layer 243-2, e.g., higher than that of the first dielectric material 244, but lower than about 6. For example, the cover dielectric material 252 may include materials such as silicon dioxide or carbon-doped silicon dioxide. Having a dielectric constant that is higher than that of the first dielectric material 244, but lower than about 6 differentiates the cover dielectric material 252 from common barrier materials used as diffusion barriers at sidewalls of conventional vias because such barrier materials are either metal nitrides such as titanium nitride or tantalum nitride (i.e., not dielectric materials) and/or dielectric materials such as aluminum nitride or silicon nitride that have dielectric constants of about 8.3 and 7.5, respectively. In some embodiments, the dielectric constant of the cover dielectric material 252 may be between about 3.5 and about 5.5. On the other hand, the dielectric constant of the dielectric material of the second dielectric layer 243-2 (i.e., the dielectric material surrounding the sidewalls of the lined via opening 251-2, e.g., the dielectric material 244) may be between about 3.5 and about 5.5. For example, a classic low-k material such as organosilicate glass, which may be used as the dielectric material surrounding the sidewalls of the lined via opening 251-2, typically has a dielectric constant of about 3.0.

The difference in dielectric constants may not be the only parameter that differentiates the cover dielectric material 252 lining the sidewalls of the lined via opening 251-2 and the dielectric material of the second dielectric layer 243-2 that surrounds the sidewalls of the lined via opening 251-2. In some embodiments, these two materials may also differ in their respective densities. In particular, the density of the cover dielectric material 252 may be higher than the density of the dielectric material of the second dielectric layer 243-2 that surrounds the sidewalls of the lined via opening 251-2. For example, in some embodiments, the density of the dielectric material of the second dielectric layer 243-2 that surrounds the sidewalls of the lined via opening 251-2 may be lower than about 1.8 gram per cubic centimeter (g/cm³). For example, a classic low-k material such as organosilicate glass may have a density of about 1.4 g/cm³. In another example, in some embodiments, the density of the cover dielectric material 252 (e.g., silicon oxide) may be higher than about 1.8 g/cm³. For example, the density of the cover dielectric material 252 may be between about 1.8 g/cm³ and 3 g/cm³, including all values and ranges therein, e.g., between about 1.9 g/cm³ and 2.9 g/cm³, or between about 1.9 g/cm³ and 2.5 g/cm³.

The method 100 may then proceed with a process 110, that includes removing the cover dielectric material deposited in the process 108 from horizontal surfaces (i.e., from surfaces substantially parallel to the support structure 242). An IC structure 210, depicted in FIG. 2E, illustrates an example result of the process 110. As shown in FIG. 2E, in the IC structure 210, the cover dielectric material 252 remains on the sidewalls of the lined via opening 251-2 and on the sidewalls of the lined top metal line opening 251-1, but is substantially absent from the bottom of the lined via opening 251-2 and from the bottom of the top metal line opening 251-1. In some embodiments, removal of the cover dielectric material 252 from the horizontal surfaces may be performed using a suitable anisotropic etching technique, such as a suitable dry etch, some examples of which have been described above. The cover dielectric material 252 remaining on the sidewalls of the lines via opening 251-2 advantageously helps covering up the dielectric material of the second dielectric layer 243-2 that surrounds the sidewalls of the lined via opening 251-2, which may be damaged when the via opening 249-2 was formed. Removing the cover dielectric material 252 from the horizontal surfaces advantageously exposes the first electrically conductive material 246 of the bottom metal line 245 at the bottom of the lined via opening 251-2.

Optionally, the method 100 may also include a process 112, in which a first SAM material may be deposited on dielectric materials, selective to electrically conductive materials (i.e. deposited on the exposed dielectric materials but not substantially deposited on the exposed electrically conductive materials). An IC structure 212, depicted in FIG. 2F, illustrates an example result of the process 112. As shown in FIG. 2F, in the IC structure 212, a first SAM material 254 may be provided on all surfaces of the IC structure 210 of the process 110 except for the bottom of the lined via opening 251-2 because the bottom of the lined via opening 251-2 is the first electrically conductive material 246 of the bottom metal line 245 while all other surfaces of the IC structure 210 were dielectric materials (e.g., the cover dielectric material 252 at the sidewalls of the lined via opening 251-2 and the sidewalls of the lined top metal line opening 251-1, either the etch stop material 248 or the dielectric material of the second dielectric layer 243-2 at the bottom of the top metal line opening 251-1, and the second dielectric material 250 at the top of the PC structure 210). Any suitable conformal deposition technique may be used to provide the first SAM material 254 in the process 112, such as ALD or CVD, as long as the first SAM material 254 is such that the molecules of the first SAM material 254 bond to dielectric materials, forming substantially a single monolayer (or a few monolayers) of molecules at the exposed surfaces of the dielectric materials, without substantially bonding to electrically conductive materials. In some embodiments, the first SAM material 254 may include any materials suitable for grafting on dielectric via sidewall to reduce/prevent metal nucleation and enable bottom-fill of the via, some example materials including, but not limited to, alkoxy, halogenated (chloro-, fluoro- etc.) and amino silane SAMs. In some embodiments, a thickness of the first SAM material 254 at the sidewalls of the lined via opening 251-2 (i.e., a dimensioned measured along the x-axis of the example coordinate system shown in FIG. 2) may be between about 0.2 and 4 nanometers, including all values and ranges therein, e.g., between about 0.3 and 2 nanometers. This may also be the thickness of the first SAM material 254 at other surfaces of the IC structure 212.

The method 100 may then proceed with a process 114, that includes depositing a second electrically conductive material into the lined via opening 251-2. An IC structure 214, depicted in FIG. 2G, illustrates an example result of the process 114. As shown in FIG. 2G, in the IC structure 214, a via 255 is formed when a second electrically conductive material 256 is provided in the lined via opening 251-2 so that an upper surface of the second electrically conductive material of the lined via opening 251-2 is substantially aligned with the bottom of the lined top metal line opening 251-1. In various embodiments, the second electrically conductive material 256 may include one or more electrically conductive materials (e.g., one electrically conductive material may line the sidewalls of the lined via opening 251-2 and another electrically conductive material may at least partially fill the remainder of the opening), and may include any of the materials described with reference to the first electrically conductive material 246. In general, the material composition of the second electrically conductive material 256 may, but does not have to be, the same as the material composition of the first electrically conductive material 246.

Any suitable process may be used to deposit the second electrically conductive material 256 in the lined via opening 251-2, such as any of the processes described with reference to the first electrically conductive material 246. Even though FIG. 2G and subsequent drawings illustrate the lined via opening 251-2 to be filled completely with the second electrically conductive material 256, in other embodiments, there may be a gap substantially in the middle of the via opening 251-2 when the second electrically conductive material 256 was deposited conformally on the sidewalls and the bottom of the via opening 251-2 but the deposition was stopped before the via opening 251-2 was filled completely.

In some embodiments when the first SAM material 254 was deposited on the sidewalls of the via opening 251-2, the second electrically conductive material 256 may be deposited in the process 114 by a selective bottom-up process in which the second electrically conductive material 256 is deposited from the bottom of the lined via opening 251-2 (i.e., from the upper surface of the first electrically conductive material 246 of the bottom metal line 245) and grows upwards, while the first SAM material 254 advantageously inhibits nucleation of metal seeds of the second electrically conductive material 256 on the sidewalls of the lined via opening 251-2 and on other surfaces of the IC structure 212 that were covered with the first SAM material 254. In such embodiments, the method 100 may also include a process 116, in which the exposed portions of the first SAM material deposited in the process 112 are removed once the via opening has been filled with an electrically conductive material. An IC structure 216, depicted in FIG. 2H, illustrates an example result of the process 116. As shown in FIG. 2H, in the IC structure 216, the first SAM material 254 is removed everywhere except where it is over the sidewalls of the lined via opening 251-2, between the cover dielectric material 252 and the second electrically conductive material 256 that was deposited in the process 114.

Using the first SAM material 254 may be advantageous in some embodiments in terms of facilitating a selective bottom-up deposition of the second electrically conductive material 256 from the top surface of the bottom metal line 245 by inhibiting nucleation of metal seeds over the sidewall of the via opening 251-2. However, in other embodiments, the first SAM material 254 as described herein may be omitted, in which case both the process 112 and the process 116 are omitted and the process 114 results in an IC structure that is substantially the same as the IC structure 216, shown in in FIG. 2H, except that it does not include the first SAM material 254 and the cover dielectric material 252 may be in contact with the second electrically conductive material 256 that was deposited in the process 114. Thus, although all of the subsequent drawings following FIG. 2H illustrate the first SAM material 254, the IC structures illustrated in these drawings could also be implemented without it.

Furthermore, it should be noted that the processes 102-116 illustrate an embodiment of the method 100 where both the top metal line opening and the via opening are patterned before the second electrically conductive material 256 of the via is deposited, a process commonly referred to as dual-Damascene. However, other embodiments of the method 100 may pattern the top metal line opening and the via opening and provide the second electrically conductive material 256 by a single-Damascene process. In such a process, first only the via opening is patterned (i.e., the via opening 249-2 is formed and the cover dielectric material 252 is provided on the walls of the via opening 249-2, resulting in the lined via opening 251-2, while exposing the first electrically conductive material 246 of the bottom metal line 245), then the patterned via opening is filled with the second electrically conductive material 256 using any of the processes described herein, and only after that the third dielectric layer 243-3 is deposited and the top metal line opening is patterned in the third dielectric layer 243-3. Thus, both single-Damascene and dual-Damascene variations of the method 100 are within the scope of the present disclosure.

Continuing with the illustration of the method 100 on FIG. 1B, the method 100 may further include a process 118, in which a second SAM material may be deposited on electrically conductive materials, selective to dielectric materials (i.e. deposited on the exposed electrically conductive materials but not substantially deposited on the exposed dielectric materials). An IC structure 218, depicted in FIG. 21, illustrates an example result of the process 118. As shown in FIG. 21, in the IC structure 218, a second SAM material 258 may be provided on all surfaces of the IC structure 216 which are not surfaces of dielectric materials. Thus, the second SAM material 258 is only provided over the second electrically conductive material 256 of the lined via opening 251-2 because exposed surfaces of the cover dielectric material 252 and of the etch stop material 248 between the second and third dielectric layers 243-2 and 243-3 or of the dielectric material of the second dielectric layer 243-2 if the etch stop material 248 is not used between the layer 243-2 and 243-3 are all dielectric materials. Any suitable conformal deposition technique may be used to provide the second SAM material 258 in the process 118, such as ALD or CVD, as long as the second SAM material 258 is such that the molecules of the second SAM material 258 bond to electrically conductive materials, forming substantially a single monolayer (or a few monolayers) of molecules at the exposed surfaces of the electrically conductive materials, without substantially bonding to the dielectric materials. In some embodiments, the second SAM material 258 may include materials suitable for grafting to metal via top and reducing/preventing TaN barrier to deposit such as aniline and short chained phosphonic acids. In some embodiments, a thickness of the second SAM material 258 over the second electrically conductive material 256 (i.e., a dimensioned measured along the z-axis of the example coordinate system shown in FIG. 2) may be between about 0.2 and 4 nanometers, including all values and ranges therein, e.g., between about 0.3 and 4 nanometers.

The method 100 may continue with a process 120, in which a barrier material may be deposited selective to the second SAM material deposited in the process 118 (i.e. deposited on all of the exposed materials except for the exposed second SAM material). An IC structure 220, depicted in FIG. 2J, illustrates an example result of the process 120. As shown in FIG. 2J, the IC structure 220 includes a barrier material 260 that is deposited over the sidewalls and the bottom of the lined top metal line opening 251-1, thus forming a yet smaller top metal line opening 261-1, where the second SAM material 258 substantially prevents deposition of the barrier material 260 over the upper surface of the second electrically conductive material 256 of the top metal line opening 261-1. Any suitable conformal deposition technique may be used to provide the barrier material 260 in the process 120, such as ALD or CVD.

In some embodiments, the barrier material 260 may include materials such as titanium nitride, tantalum nitride, or silicon nitride. In general, the barrier material 260 may include any material through which the atoms of the electrically conductive material of the top metal line (e.g., copper), deposited in a later process of the method 100, may not substantially diffuse. Thus, the barrier material 260 is intended to provide hermiticity in terms of reducing or eliminating diffusion of the atoms of the electrically conductive material of the top metal line into the dielectric stack and reaching the support structure 242 (that's why the lined top metal line opening 261-1 with the barrier material 260 may be referred to as a “hermetic lined top metal line opening” 261-1).

In some embodiments, a thickness of the barrier material 260 (i.e., a dimensioned measured along the z-axis for the barrier material 260 provided over the horizontal surfaces and a dimension measured in an x-y plane for the barrier material 260 provided over the vertical surfaces shown in FIG. 2K) may be between about 0.5 and 4 nanometers. In some implementations, the thickness of the barrier material 260 may be selected to be thick enough to substantially prevent diffusion of the atoms of the electrically conductive material of the top metal line while being thin enough so that the hermetic top metal line opening 261-1 is still large enough to have sufficient conductivity when the hermetic opening 261-1 is filled with an electrically conductive material. A dash-dotted line 259, shown in the top-down view of FIG. 2J (and FIG. 2K), illustrates a sidewall 263 of the hermetic opening 261-1, the sidewall 263 indicated in the cross-sectional side view of the y-z plane of FIG. 2J (and FIG. 2K).

The method 100 may then proceed with a process 122, in which the second SAM material deposited in the process 118 is removed before the hermetic lined top metal line opening 261-1 is filled with an electrically conductive material. An IC structure 222, depicted in FIG. 2K, illustrates an example result of the process 122. As shown in FIG. 2K, the IC structure 222, the second SAM material 258 is removed, exposing the upper surface of the second electrically conductive material 256 in the lined via opening 251-2. In some embodiments, processes such as H2 plasma may be used to remove the second SAM material 258 in the process 122

Next, the method 100 may include a process 124, that includes depositing a third electrically conductive material into the hermetic top metal line opening 261-1. An IC structure 224, depicted in FIG. 2L, illustrates an example result of the process 124. As shown in FIG. 2L, in the IC structure 224, a third electrically conductive material 262 is provided in the hermetic top metal line opening 261-1 in which the second SAM material 258 has been removed to expose the second electrically conductive material 256 in the lined via opening 251-2. In various embodiments, the third electrically conductive material 262 may include one or more electrically conductive materials (e.g., one electrically conductive material may line the sidewalls of the hermetic top metal line opening 261-1 and another electrically conductive material may at least partially fill the remainder of the opening), and may include any of the materials described with reference to the first electrically conductive material 246. In general, the material composition of the third electrically conductive material 262 may, but does not have to, be the same as the material composition of the first electrically conductive material 246 or the second electrically conductive material 256. Any suitable process may be used to deposit the third electrically conductive material 262 in the hermetic top metal line opening 261-1, such as any of the processes described with reference to the first electrically conductive material 246.

The method 100 may end with a process 126, in which excess of the third electrically conductive material 262 is removed to form a top metal line. An IC structure 226, depicted in FIG. 2M, illustrates an example result of the process 126. As shown in FIG. 2M, in the IC structure 226, excess of the third electrically conductive material 262 is removed, e.g., so that the third electrically conductive material 262 is only provided in the hermetic lined top metal line opening 261-1 but not over the upper surface of the barrier material 260 over the third dielectric layer 243-3, to form a top metal line 265. In some embodiments, any suitable process, such as CMP, may be used to remove the excess of the third electrically conductive material 262 to form the top metal line 265. Together, the bottom metal line 245, the top metal line 265, and the via 255 having one end coupled to the bottom metal line 245 and another end coupled to the top metal line 265, together with the respective dielectric materials surrounding these structures, form a metallization stack 270 of the IC structure 226. The use of the second SAM material 258 in the method 100 may enable an improved integration of the via 255 in the metallization stack 270, where the via 255 is electrically coupled between/to the bottom metal line 245 and the top metal line 265.

The use of the cover dielectric material 252 and the use of the second SAM material 258 in the method 100, whether the method 100 was performed using dual-Damascene or single-Damascene approaches, leaves several characteristic features in the IC structure 226. One characteristic feature is that at least a portion of the sidewalls of the via 255 may be lined with the cover dielectric material 252 so that the cover dielectric material 252 is between the dielectric material of the second metallization layer 243-2 and the electrically conductive material 256 of the via 255, where the dielectric constant of the cover dielectric material 252 is higher than the dielectric constant of the dielectric material of the second metallization layer 243-2 and is lower than about 6 and the density of the cover dielectric material 252 is higher than the density of the dielectric material of the second metallization layer 243-2. Another characteristic feature is that the electrically conductive material 256 of the via 255 may be in direct contact with an electrically conductive fill material (as opposed to, e.g., some kind of a barrier material such as tantalum nitride) of the top metal line 265. Yet another characteristic feature is that the electrically conductive material 256 of the via 255 may be in direct contact with the electrically conductive material 246 of the bottom metal line 245. One more characteristic feature is that the barrier material 260 may be provided in a portion between the second and the third metallization layers 243-2 and 243-3, where the barrier material 260 discontinues (i.e., is absent) between the top of the via 255 and the bottom of the top metal line 265. Phrased differently, the barrier material 260 may be between an electrically conductive material of the top metal line 265 and the dielectric material of the second metallization layer 243-2.

### Example Devices

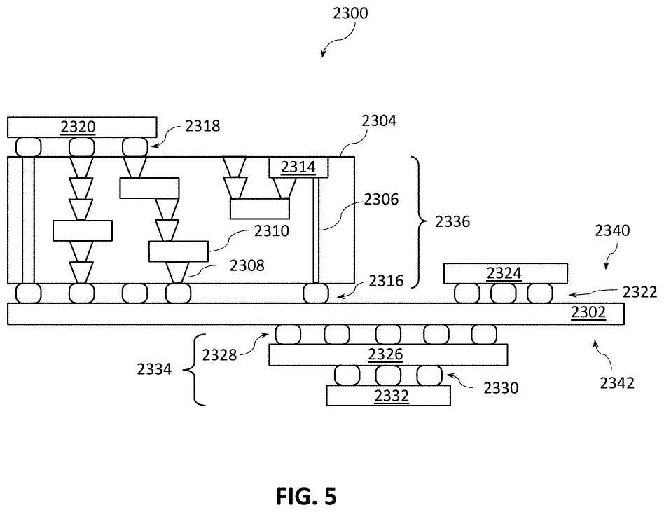

The IC structures with metallization stacks where SAMs were applied for improved via integration, disclosed herein, may be included in any suitable electronic device. FIGS. 5-8 illustrate various examples of apparatuses that may include one or more of the IC structures disclosed herein.

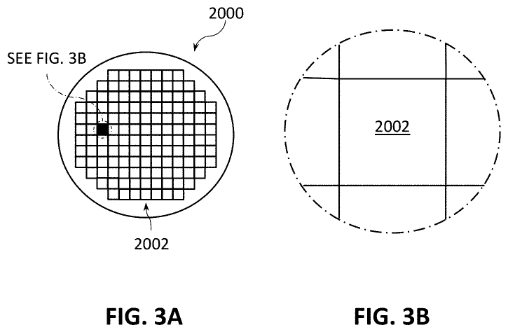

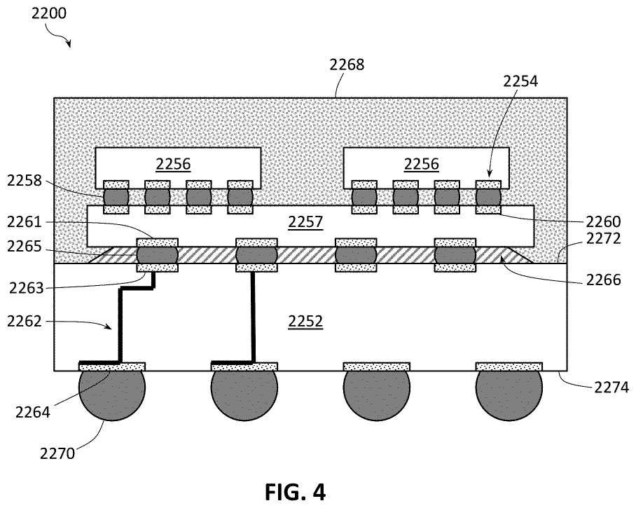

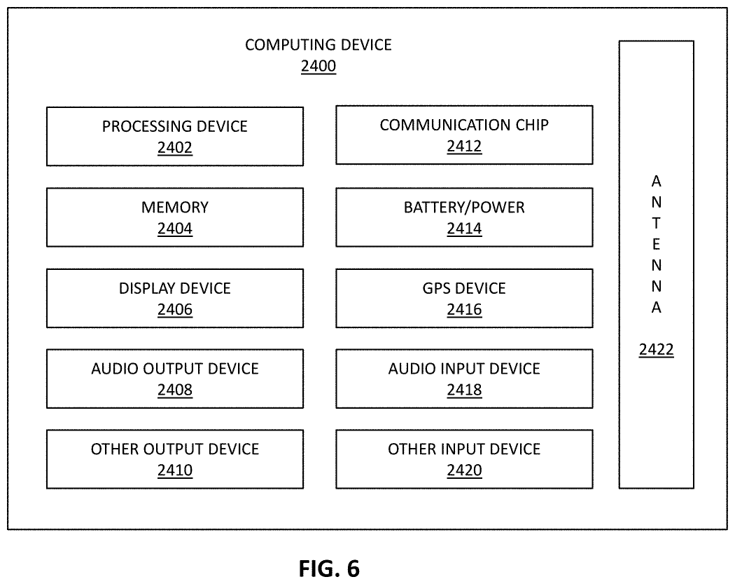

FIGS. 3A-3B are top views of a wafer 2000 and dies 2002 that may include one or more metallization stacks where SAMs were applied for improved via integration in accordance with any of the embodiments disclosed herein. In some embodiments, the dies 2002 may be included in an IC package, in accordance with any of the embodiments disclosed herein. For example, any of the dies 2002 may serve as any of the dies 2256 in an IC package 2200 shown in FIG. 4. The wafer 2000 may be composed of semiconductor material and may include one or more dies 2002 having IC structures formed on a surface of the wafer 2000. Each of the dies 2002 may be a repeating unit of a semiconductor product that includes any suitable IC (e.g., ICs including one or more metallization stacks where SAMs were applied for improved via integration as described herein). After the fabrication of the semiconductor product is complete (e.g., after manufacture of one or more layers of the metallization stacks where SAMs were applied for improved via integration as described herein), the wafer 2000 may undergo a singulation process in which each of the dies 2002 is separated from one another to provide discrete “chips” of the semiconductor product. In particular, devices that include one or more metallization stacks where SAMs were applied for improved via integration as disclosed herein may take the form of the wafer 2000 (e.g., not singulated) or the form of the die 2002 (e.g., singulated). The die 2002 may include supporting circuitry to route electrical signals to various memory cells, transistors, capacitors, as well as any other IC components. In some embodiments, the wafer 2000 or the die 2002 may implement or include a memory device (e.g., an SRAM device), a logic device (e.g., an AND, OR, NAND, or NOR gate), or any other suitable circuit element. Multiple ones of these devices may be combined on a single die 2002. For example, a memory array formed by multiple memory devices may be formed on a same die 2002 as a processing device (e.g., the processing device 2402 of FIG. 6) or other logic that is configured to store information in the memory devices or execute instructions stored in the memory array.

FIG. 4 is a side, cross-sectional view of an example IC package 2200 that may include one or more metallization stacks where SAMs were applied for improved via integration in accordance with any of the embodiments disclosed herein. In some embodiments, the IC package 2200 may be a system-in-package (SiP).

The package substrate 2252 may be formed of a dielectric material (e.g., a ceramic, a buildup film, an epoxy film having filler particles therein, etc.), and may have conductive pathways extending through the dielectric material between the face 2272 and the face 2274, or between different locations on the face 2272, and/or between different locations on the face 2274.

The package substrate 2252 may include conductive contacts 2263 that are coupled to conductive pathways 2262 through the package substrate 2252, allowing circuitry within the dies 2256 and/or the interposer 2257 to electrically couple to various ones of the conductive contacts 2264 (or to other devices included in the package substrate 2252, not shown).

The IC package 2200 may include an interposer 2257 coupled to the package substrate 2252 via conductive contacts 2261 of the interposer 2257, first-level interconnects 2265, and the conductive contacts 2263 of the package substrate 2252. The first-level interconnects 2265 illustrated in FIG. 4 are solder bumps, but any suitable first-level interconnects 2265 may be used. In some embodiments, no interposer 2257 may be included in the IC package 2200; instead, the dies 2256 may be coupled directly to the conductive contacts 2263 at the face 2272 by first-level interconnects 2265.

The IC package 2200 may include one or more dies 2256 coupled to the interposer 2257 via conductive contacts 2254 of the dies 2256, first-level interconnects 2258, and conductive contacts 2260 of the interposer 2257. The conductive contacts 2260 may be coupled to conductive pathways (not shown) through the interposer 2257, allowing circuitry within the dies 2256 to electrically couple to various ones of the conductive contacts 2261 (or to other devices included in the interposer 2257, not shown). The first-level interconnects 2258 illustrated in FIG. 4 are solder bumps, but any suitable first-level interconnects 2258 may be used. As used herein, a “conductive contact” may refer to a portion of electrically conductive material (e.g., metal) serving as an interface between different components; conductive contacts may be recessed in, flush with, or extending away from a surface of a component, and may take any suitable form (e.g., a conductive pad or socket).

In some embodiments, an underfill material 2266 may be disposed between the package substrate 2252 and the interposer 2257 around the first-level interconnects 2265, and a mold compound 2268 may be disposed around the dies 2256 and the interposer 2257 and in contact with the package substrate 2252. In some embodiments, the underfill material 2266 may be the same as the mold compound 2268. Example materials that may be used for the underfill material 2266 and the mold compound 2268 are epoxy mold materials, as suitable. Second-level interconnects 2270 may be coupled to the conductive contacts 2264. The second-level interconnects 2270 illustrated in FIG. 4 are solder balls (e.g., for a ball grid array arrangement), but any suitable second-level interconnects 2270 may be used (e.g., pins in a pin grid array arrangement or lands in a land grid array arrangement). The second-level interconnects 2270 may be used to couple the IC package 2200 to another component, such as a circuit board (e.g., a motherboard), an interposer, or another IC package, as known in the art and as discussed below with reference to FIG. 5.

The dies 2256 may take the form of any of the embodiments of the die 2002 discussed herein (e.g., may include any of the embodiments of the metallization stacks where SAMs were applied for improved via integration as described herein). In embodiments in which the IC package 2200 includes multiple dies 2256, the IC package 2200 may be referred to as a multi-chip package (MCP). The dies 2256 may include circuitry to perform any desired functionality. For example, one or more of the dies 2256 may be logic dies (e.g., silicon-based dies), and one or more of the dies 2256 may be memory dies (e.g., high bandwidth memory). In some embodiments, any of the dies 2256 may include one or more metallization stacks where SAMs were applied for improved via integration as discussed above; in some embodiments, at least some of the dies 2256 may not include any metallization stacks where SAMs were applied for improved via integration.

The IC package 2200 illustrated in FIG. 4 may be a flip chip package, although other package architectures may be used. For example, the IC package 2200 may be a ball grid array (BGA) package, such as an embedded wafer-level ball grid array (eWLB) package. In another example, the IC package 2200 may be a wafer-level chip scale package (WLCSP) or a panel fan-out (FO) package. Although two dies 2256 are illustrated in the IC package 2200 of FIG. 4, an IC package 2200 may include any desired number of the dies 2256. An IC package 2200 may include additional passive components, such as surface-mount resistors, capacitors, and inductors disposed on the first face 2272 or the second face 2274 of the package substrate 2252, or on either face of the interposer 2257. More generally, an IC package 2200 may include any other active or passive components known in the art.

FIG. 5 is a cross-sectional side view of an IC device assembly 2300 that may include components having one or more metallization stacks where SAMs were applied for improved via integration in accordance with any of the embodiments disclosed herein. The IC device assembly 2300 includes a number of components disposed on a circuit board 2302 (which may be, e.g., a motherboard). The IC device assembly 2300 includes components disposed on a first face 2340 of the circuit board 2302 and an opposing second face 2342 of the circuit board 2302; generally, components may be disposed on one or both faces 2340 and 2342. In particular, any suitable ones of the components of the IC device assembly 2300 may include any of one or more metallization stacks where SAMs were applied for improved via integration in accordance with any of the embodiments disclosed herein; e.g., any of the IC packages discussed below with reference to the IC device assembly 2300 may take the form of any of the embodiments of the IC package 2200 discussed above with reference to FIG. 4 (e.g., may include one or more metallization stacks where SAMs were applied for improved via integration provided on a die 2256).

In some embodiments, the circuit board 2302 may be a printed circuit board (PCB) including multiple metal layers separated from one another by layers of dielectric material and interconnected by electrically conductive vias. Any one or more of the metal layers may be formed in a desired circuit pattern to route electrical signals (optionally in conjunction with other metal layers) between the components coupled to the circuit board 2302. In other embodiments, the circuit board 2302 may be a non-PCB substrate.

The IC device assembly 2300 illustrated in FIG. 5 includes a package-on-interposer structure 2336 coupled to the first face 2340 of the circuit board 2302 by coupling components 2316. The coupling components 2316 may electrically and mechanically couple the package-on-interposer structure 2336 to the circuit board 2302, and may include solder balls (e.g., as shown in FIG. 5), male and female portions of a socket, an adhesive, an underfill material, and/or any other suitable electrical and/or mechanical coupling structure.

The package-on-interposer structure 2336 may include an IC package 2320 coupled to an interposer 2304 by coupling components 2318. The coupling components 2318 may take any suitable form for the application, such as the forms discussed above with reference to the coupling components 2316. The IC package 2320 may be or include, for example, a die (the die 2002 of FIG. 3B), an IC device, or any other suitable component. In particular, the IC package 2320 may include one or more metallization stacks where SAMs were applied for improved via integration as described herein. Although a single IC package 2320 is shown in FIG. 5, multiple IC packages may be coupled to the interposer 2304; indeed, additional interposers may be coupled to the interposer 2304. The interposer 2304 may provide an intervening substrate used to bridge the circuit board 2302 and the IC package 2320. Generally, the interposer 2304 may spread a connection to a wider pitch or reroute a connection to a different connection. For example, the interposer 2304 may couple the IC package 2320 (e.g., a die) to a BGA of the coupling components 2316 for coupling to the circuit board 2302. In the embodiment illustrated in FIG. 5, the IC package 2320 and the circuit board 2302 are attached to opposing sides of the interposer 2304; in other embodiments, the IC package 2320 and the circuit board 2302 may be attached to a same side of the interposer 2304. In some embodiments, three or more components may be interconnected by way of the interposer 2304.

The interposer 2304 may be formed of an epoxy resin, a fiberglass-reinforced epoxy resin, a ceramic material, or a polymer material such as polyimide. In some implementations, the interposer 2304 may be formed of alternate rigid or flexible materials that may include the same materials described above for use in a semiconductor substrate, such as silicon, germanium, and other group III-V and group IV materials. The interposer 2304 may include any number of metal lines 2310, vias 2308, and through-silicon vias (TSVs) 2306. In some embodiments, any of the vias 2308 may be integrated by application of SAMs, as described herein. The interposer 2304 may further include embedded devices 2314, including both passive and active devices. Such devices may include, but are not limited to, capacitors, decoupling capacitors, resistors, inductors, fuses, diodes, transformers, sensors, electrostatic discharge (ESD) protection devices, and memory devices. More complex devices such as RF devices, power amplifiers, power management devices, antennas, arrays, sensors, and microelectromechanical systems (MEMS) devices may also be formed on the interposer 2304. The package-on-interposer structure 2336 may take the form of any of the package-on-interposer structures known in the art.

The IC device assembly 2300 may include an IC package 2324 coupled to the first face 2340 of the circuit board 2302 by coupling components 2322. The coupling components 2322 may take the form of any of the embodiments discussed above with reference to the coupling components 2316, and the IC package 2324 may take the form of any of the embodiments discussed above with reference to the IC package 2320.

The IC device assembly 2300 illustrated in FIG. 5 includes a package-on-package structure 2334 coupled to the second face 2342 of the circuit board 2302 by coupling components 2328. The package-on-package structure 2334 may include an IC package 2326 and an IC package 2332 coupled together by coupling components 2330 such that the IC package 2326 is disposed between the circuit board 2302 and the IC package 2332. The coupling components 2328 and 2330 may take the form of any of the embodiments of the coupling components 2316 discussed above, and the IC packages 2326 and 2332 may take the form of any of the embodiments of the IC package 2320 discussed above. The package-on-package structure 2334 may be configured in accordance with any of the package-on-package structures known in the art.

FIG. 6 is a block diagram of an example computing device 2400 that may include one or more components with one or more metallization stacks where SAMs were applied for improved via integration in accordance with any of the embodiments disclosed herein. For example, any suitable ones of the components of the computing device 2400 may include a die (e.g., the die 2002, shown in FIG. 3B) including one or more metallization stacks where SAMs were applied for improved via integration in accordance with any of the embodiments disclosed herein. Any of the components of the computing device 2400 may include an IC package 2200 (e.g., as shown in FIG. 4). Any of the components of the computing device 2400 may include an IC device assembly 2300 (e.g., as shown in FIG. 5).

A number of components are illustrated in FIG. 6 as included in the computing device 2400, but any one or more of these components may be omitted or duplicated, as suitable for the application. In some embodiments, some or all of the components included in the computing device 2400 may be attached to one or more motherboards. In some embodiments, some or all of these components are fabricated onto a single SoC die.

Additionally, in various embodiments, the computing device 2400 may not include one or more of the components illustrated in FIG. 6, but the computing device 2400 may include interface circuitry for coupling to the one or more components. For example, the computing device 2400 may not include a display device 2406, but may include display device interface circuitry (e.g., a connector and driver circuitry) to which a display device 2406 may be coupled. In another set of examples, the computing device 2400 may not include an audio input device 2418 or an audio output device 2408, but may include audio input or output device interface circuitry (e.g., connectors and supporting circuitry) to which an audio input device 2418 or audio output device 2408 may be coupled.

The computing device 2400 may include a processing device 2402 (e.g., one or more processing devices). As used herein, the term “processing device” or “processor” may refer to any device or portion of a device that processes electronic data from registers and/or memory to transform that electronic data into other electronic data that may be stored in registers and/or memory. The processing device 2402 may include one or more digital signal processors (DSPs), application-specific ICs (ASICs), central processing units (CPUs), graphics processing units (GPUs), cryptoprocessors (specialized processors that execute cryptographic algorithms within hardware), server processors, or any other suitable processing devices. The computing device 2400 may include a memory 2404, which may itself include one or more memory devices such as volatile memory (e.g., DRAM), nonvolatile memory (e.g., read-only memory (ROM)), flash memory, solid state memory, and/or a hard drive. In some embodiments, the memory 2404 may include memory that shares a die with the processing device 2402.

In some embodiments, the computing device 2400 may include a communication chip 2412 (e.g., one or more communication chips). For example, the communication chip 2412 may be configured for managing wireless communications for the transfer of data to and from the computing device 2400. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

The communication chip 2412 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultramobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication chip 2412 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication chip 2412 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 2412 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication chip 2412 may operate in accordance with other wireless protocols in other embodiments. The computing device 2400 may include an antenna 2422 to facilitate wireless communications and/or to receive other wireless communications (such as AM or FM radio transmissions).

In some embodiments, the communication chip 2412 may manage wired communications, such as electrical, optical, or any other suitable communication protocols (e.g., the Ethernet). As noted above, the communication chip 2412 may include multiple communication chips. For instance, a first communication chip 2412 may be dedicated to shorter-range wireless communications such as Wi-Fi or Bluetooth, and a second communication chip 2412 may be dedicated to longer-range wireless communications such as global positioning system (GPS), EDGE, GPRS, CDMA, WiMAX, LTE, EV-DO, or others. In some embodiments, a first communication chip 2412 may be dedicated to wireless communications, and a second communication chip 2412 may be dedicated to wired communications.

The computing device 2400 may include battery/power circuitry 2414. The battery/power circuitry 2414 may include one or more energy storage devices (e.g., batteries or capacitors) and/or circuitry for coupling components of the computing device 2400 to an energy source separate from the computing device 2400 (e.g., AC line power).

The computing device 2400 may include a display device 2406 (or corresponding interface circuitry, as discussed above). The display device 2406 may include any visual indicators, such as a heads-up display, a computer monitor, a projector, a touchscreen display, a liquid crystal display (LCD), a light-emitting diode display, or a flat panel display, for example.

The computing device 2400 may include an audio output device 2408 (or corresponding interface circuitry, as discussed above). The audio output device 2408 may include any device that generates an audible indicator, such as speakers, headsets, or earbuds, for example.

The computing device 2400 may include an audio input device 2418 (or corresponding interface circuitry, as discussed above). The audio input device 2418 may include any device that generates a signal representative of a sound, such as microphones, microphone arrays, or digital instruments (e.g., instruments having a musical instrument digital interface (MIDI) output).

The computing device 2400 may include a GPS device 2416 (or corresponding interface circuitry, as discussed above). The GPS device 2416 may be in communication with a satellite-based system and may receive a location of the computing device 2400, as known in the art.

The computing device 2400 may include an other output device 2410 (or corresponding interface circuitry, as discussed above). Examples of the other output device 2410 may include an audio codec, a video codec, a printer, a wired or wireless transmitter for providing information to other devices, or an additional storage device.

The computing device 2400 may include an other input device 2420 (or corresponding interface circuitry, as discussed above). Examples of the other input device 2420 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

The computing device 2400 may have any desired form factor, such as a handheld or mobile computing device (e.g., a cell phone, a smart phone, a mobile internet device, a music player, a tablet computer, a laptop computer, a netbook computer, an ultrabook computer, a personal digital assistant (PDA), an ultramobile personal computer, etc.), a desktop computing device, a server or other networked computing component, a printer, a scanner, a monitor, a set-top box, an entertainment control unit, a vehicle control unit, a digital camera, a digital video recorder, or a wearable computing device. In some embodiments, the computing device 2400 may be any other electronic device that processes data.

### Select Examples

The following paragraphs provide various examples of the embodiments disclosed herein.

Example 1 provides am IC structure that includes a support structure (e.g., a support structure 242, shown in the present drawings, e.g., a substrate); a stack of a first, a second, and a third metallization layers provided over the support structure, where the first metallization layer includes a bottom electrically conductive line, the third metallization layer includes a top electrically conductive line, and the second metallization layer is between the first and the third metallization layers and includes a via having a first end coupled to the bottom electrically conductive line and a second end coupled to the top electrically conductive line. In such an IC structure, the second metallization layer includes a first dielectric material that encloses sidewalls of the via, at least a portion of the sidewalls of the via is lined with a second dielectric material so that the second dielectric material is between the first dielectric material and an electrically conductive material of the via, and a dielectric constant of the second dielectric material is higher than a dielectric constant of the first dielectric material and is lower than about 6.

Example 2 provides the IC structure according to example 1, where the dielectric constant of the first dielectric material is lower than 3.5.

Example 3 provides the IC structure according to examples 1 or 2, where the dielectric constant of the second dielectric material is between about 3.5 and about 5.5.

Example 4 provides the IC structure according to any one of the preceding examples, where a density of the second dielectric material is higher than a density of the first dielectric material.

Example 5 provides the IC structure according to example 4, where the density of the first dielectric material is lower than about 1.8 gram per cubic centimeter.

Example 6 provides the IC structure according to examples 4 or 5, where the density of the second dielectric material is above 1.8 gram per cubic centimeter.

Example 7 provides the IC structure according to any one of examples 4-6, where the density of the second dielectric material is between about 1.8 and 3 gram per cubic centimeter, e.g., between about 1.9 and about 2.5 gram per cubic centimeter.

Example 8 provides the IC structure according to any one of the preceding examples, further including a barrier material (e.g., the barrier material 260, shown in the present drawings) in a portion between the second and the third metallization layers, where the barrier material discontinues (i.e., is absent) between the second end of the via and the top electrically conductive line.

Example 9 provides the IC structure according to example 8, where the barrier material is between an electrically conductive material of the top electrically conductive line of the third metallization layer and the first dielectric material.

Example 10 provides the IC structure according to any one of the preceding examples, further including an etch stop material (e.g., the etch stop material 248, shown in the present drawings) between the second and the third metallization layers, where the etch stop material discontinues (i.e., is absent) between the second end of the via and the top electrically conductive line.

Example 11 provides the IC structure according to example 10, where the etch stop material is between the barrier material and the first dielectric material.

Example 12 provides the IC structure according to any one of the preceding examples, where the electrically conductive material of the via is in contact with an electrically conductive fill material of the top electrically conductive line.

Example 13 provides the IC structure according to any one of the preceding examples, where the electrically conductive material of the via is in direct contact with an electrically conductive material of the bottom electrically conductive line.

Example 14 provides an IC structure that includes a support structure (e.g., a support structure 242, shown in the present drawings, e.g., a substrate); a layer of a first dielectric material provided over the support structure; and a via extending through the layer of the first dielectric material. In such an IC structure, a second dielectric material is provided over at least a portion of one or more sidewalls of the via so that the second dielectric material is between the first dielectric material and an electrically conductive material of the via, and a dielectric constant of the second dielectric material is higher than a dielectric constant of the first dielectric material and is lower than about 6.

Example 15 provides the IC structure according to example 14, where a density of the second dielectric material is higher than a density of the first dielectric material.

Example 16 provides a method of fabricating an IC structure. The method includes providing a bottom electrically conductive line in a first dielectric layer provided over a support structure so that the top of the bottom electrically conductive line is aligned with the top of the first dielectric layer and so that a longitudinal axis of the bottom electrically conductive line is substantially parallel to the support structure (i.e., so that the bottom electrically conductive line extends in a direction that is substantially parallel to the support structure). The method further includes providing a second dielectric layer over the first dielectric layer with the bottom electrically conductive line. The second dielectric layer includes a first dielectric material and a via extending through the first dielectric material, where the via has a first end coupled to the bottom electrically conductive line. At least a portion of one or more sidewalls of the via is lined with a cover dielectric material (e.g., the material 252, shown in the present drawings) so that the cover dielectric material is between the first dielectric material and one or more electrically conductive materials of the via. A dielectric constant of the cover dielectric material is higher than a dielectric constant of the first dielectric material and is lower than about 6. The method also includes providing a third dielectric layer so that the second dielectric layer is between the first dielectric layer and the third dielectric layer and patterning the third dielectric layer to form a top line opening for a top electrically conductive line, where the top line opening extends in a direction that is substantially parallel to the support structure and a bottom of the top line opening exposes the one or more electrically conductive materials of the via. Furthermore, the method includes providing a SAM material (e.g., the SAM material 258, shown in the present drawings) that is selective to dielectric materials (i.e., that is not substantially deposited over dielectric materials) over the one or more electrically conductive materials of the via exposed by the top line opening, depositing a barrier material to line sidewalls and a bottom of the top line opening without substantially depositing the barrier material over the SAM material, and depositing one or more electrically conductive materials in the top line opening lined with the barrier material to form the top electrically conductive line, where a second end of the via is coupled to the top electrically conductive line.

Example 17 provides the method according to example 16, where the method further includes removing the SAM material after depositing the barrier material and prior to depositing the one or more electrically conductive materials to form the top electrically conductive line.

Example 18 provides the method according to examples 16 or 17, where providing the via, the third dielectric layer, and the top line opening includes: providing a stack of the second dielectric layer and the third dielectric layer over the first dielectric layer with the bottom electrically conductive line; patterning the third dielectric layer to form the top line opening before providing the via; patterning the second dielectric layer, through the top line opening in the third dielectric layer, to form a via opening extending through the first dielectric material of the second dielectric layer; depositing the cover dielectric material to line sidewalls and bottoms of the via opening and the top line opening; removing the cover dielectric material from all surfaces that are substantially parallel to the support structure to form a lined via opening as the via opening with the cover dielectric material lining the sidewalls of the via opening and absent from the bottom of the via opening; and filling the lined via opening with the one or more electrically conductive materials of the via.

Example 19 provides the method according to example 18, where the SAM material is a first SAM material, and the method further includes: after removing the cover dielectric material to form the lined via opening and before filling the lined via opening with the one or more electrically conductive materials of the via, providing a second SAM material (e.g., the SAM material 254, shown in the present drawings) that is selective to electrically conductive materials (i.e., that is not substantially deposited over electrically conductive materials) over the sidewalls and the bottoms of the top line opening and over one or more sidewalls of the lined via opening; and removing exposed portions of the second SAM material after filling the lined via opening with the one or more electrically conductive materials of the via and before providing the first SAM material.

Example 20 provides the method according to examples 18 or 19, where depositing the cover dielectric material includes performing a conformal deposition process to deposit the cover dielectric material on the sidewalls and the bottoms of the via opening and the top line opening.

Example 21 provides the method according to any one of examples 16-20, where the IC structure is the IC structure according to any one of examples 1-13, where the first, second, and third dielectric layers of examples 16-20 form bases of, or included in, respectively, the first, second, and third metallization layers of examples 1-13, a dielectric material of the second dielectric layer of examples 16-20 is the first dielectric material of examples 1-13, and the cover dielectric material of examples 16-20 is the second dielectric material of examples 1-13.

Example 22 provides the method according to example 21, further including processes for forming the IC structure as the IC structure according to any one of examples 1-13.

Example 23 provides an IC package that includes an IC die that includes an IC structure according to any one of the preceding examples (e.g., the IC structure according to any one of examples 1-15 and/or an IC structure formed according to the method according to any one of examples 16-22) and a further IC component, coupled to the IC die.

Example 24 provides the IC package according to example 23, where the further component is one of a package substrate, a flexible substrate, or an interposer.

Example 25 provides the IC package according to examples 23 or 24, where the further component is coupled to the IC die via one or more first-level interconnects.

Example 26 provides the IC package according to example 25, where the one or more first-level interconnects include one or more solder bumps, solder posts, or bond wires.

Example 27 provides a computing device that includes a circuit board; and an IC die coupled to the circuit board, where the IC die includes one or more of: 1) one or more of the IC structures according to any one of claims 1-15, 2) one or more of the IC structures formed according to the method according to any one of claims 16-22, and 3) one or more of IC packages according to any one of the preceding examples (e.g., each IC package may be an IC package according to any one of examples 23-26).

Example 28 provides the computing device according to example 27, where the computing device is a wearable computing device (e.g., a smart watch) or handheld computing device (e.g., a mobile phone).

Example 29 provides the computing device according to examples 27 or 28, where the computing device is a server processor.

Example 30 provides the computing device according to examples 27 or 28, where the computing device is a motherboard.

Example 31 provides the computing device according to any one of examples 27-30, where the computing device further includes one or more communication chips and an antenna.

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize. These modifications may be made to the disclosure in light of the above detailed description.

1. An integrated circuit (IC) structure, comprising:
a support structure;
a stack of a first, a second, and a third metallization layers over the support structure, where the first metallization layer includes a bottom electrically conductive line, the third metallization layer includes a top electrically conductive line, and the second metallization layer is between the first and the third metallization layers and includes a via having a first end coupled to the bottom electrically conductive line and a second end coupled to the top electrically conductive line,
wherein:
the second metallization layer includes a first dielectric material that encloses sidewalls of the via,
at least a portion of the sidewalls of the via is lined with a second dielectric material so that the second dielectric material is between the first dielectric material and an electrically conductive material of the via, and
a dielectric constant of the second dielectric material is higher than a dielectric constant of the first dielectric material and is lower than about 6.

2. The IC structure according to claim 1, wherein the dielectric constant of the first dielectric material is lower than 3.5.

3. The IC structure according to claim 1, wherein the dielectric constant of the second dielectric material is between about 3.5 and about 5.5.

4. The IC structure according to claim 1, wherein a density of the second dielectric material is higher than a density of the first dielectric material.

5. The IC structure according to claim 4, wherein the density of the first dielectric material is lower than about 1.8 gram per cubic centimeter.

6. The IC structure according to claim 4, wherein the density of the second dielectric material is above 1.8 gram per cubic centimeter.

7. The IC structure according to claim 4, wherein the density of the second dielectric material is between about 1.9 and about 2.5 gram per cubic centimeter.

8. The IC structure according to claim 1, further comprising a barrier material in a portion between the second and the third metallization layers, where the barrier material discontinues between the second end of the via and the top electrically conductive line.

9. The IC structure according to claim 8, wherein the barrier material is between the top electrically conductive line of the third metallization layer and the first dielectric material.

10. The IC structure according to claim 9, further comprising an etch stop material between the second and the third metallization layers, where the etch stop material discontinues between the second end of the via and the top electrically conductive line.

11. The IC structure according to claim 10, wherein the etch stop material is between the barrier material and the first dielectric material.

12. The IC structure according to claim 1, wherein the electrically conductive material of the via is in contact with an electrically conductive fill material of the top electrically conductive line.

13. The IC structure according to claim 1, wherein the electrically conductive material of the via is in contact with an electrically conductive material of the bottom electrically conductive line.

14. An integrated circuit (IC) structure, comprising:
a layer of a first dielectric material; and
a via extending through the layer of the first dielectric material;
wherein:
a second dielectric material is provided over at least a portion of one or more sidewalls of the via so that the second dielectric material is between the first dielectric material and an electrically conductive material of the via, and
a dielectric constant of the second dielectric material is higher than a dielectric constant of the first dielectric material and is lower than about 6.

15. The IC structure according to claim 14, wherein a density of the second dielectric material is higher than a density of the first dielectric material.

16. A method of fabricating an integrated circuit (IC) structure, the method comprising:
providing a bottom electrically conductive line in a first dielectric layer over a support structure;
providing a second dielectric layer over the first dielectric layer with the bottom electrically conductive line, where:
the second dielectric layer includes a first dielectric material and a via extending through the first dielectric material, the via having a first end coupled to the bottom electrically conductive line,
at least a portion of one or more sidewalls of the via is lined with a cover dielectric material so that the cover dielectric material is between the first dielectric material and one or more electrically conductive materials of the via, and
a dielectric constant of the cover dielectric material is higher than a dielectric constant of the first dielectric material and is lower than about 6;
providing a third dielectric layer so that the second dielectric layer is between the first dielectric layer and the third dielectric layer;
patterning the third dielectric layer to form a top line opening for a top electrically conductive line, where the top line opening extends in a direction that is substantially parallel to the support structure and a bottom of the top line opening exposes the one or more electrically conductive materials of the via;
providing a self-assembled monolayer (SAM) material that is selective to dielectric materials over the one or more electrically conductive materials of the via exposed by the top line opening;
depositing a barrier material to line sidewalls and a bottom of the top line opening without substantially depositing the barrier material over the SAM material; and
depositing one or more electrically conductive materials in the top line opening lined with the barrier material to form the top electrically conductive line, where a second end of the via is coupled to the top electrically conductive line.

17. The method according to claim 16, wherein the method further includes removing the SAM material after depositing the barrier material and prior to depositing the one or more electrically conductive materials to form the top electrically conductive line.

18. The method according to claim 16, wherein providing the via, the third dielectric layer, and the top line opening includes:
providing a stack of the second dielectric layer and the third dielectric layer over the first dielectric layer with the bottom electrically conductive line;
patterning the third dielectric layer to form the top line opening before providing the via;
patterning the second dielectric layer, through the top line opening, to form a via opening extending through the first dielectric material of the second dielectric layer;
depositing the cover dielectric material to line sidewalls and bottoms of the via opening and the top line opening;
removing the cover dielectric material from all surfaces that are substantially parallel to the support structure to form a lined via opening as the via opening with the cover dielectric material lining the sidewalls of the via opening and absent from the bottom of the via opening; and
filling the lined via opening with the one or more electrically conductive materials of the via.

19. The method according to claim 18, wherein the SAM material is a first SAM material, and the method further includes:
after removing the cover dielectric material to form the lined via opening and before filling the lined via opening with the one or more electrically conductive materials of the via, providing a second SAM material that is selective to electrically conductive materials over the sidewalls and the bottoms of the top line opening and over one or more sidewalls of the lined via opening, and
removing exposed portions of the second SAM material after filling the lined via opening with the one or more electrically conductive materials of the via.

20. The method according to claim 18, wherein depositing the cover dielectric material includes performing a conformal deposition process to deposit the cover dielectric material on the sidewalls and the bottoms of the via opening and the top line opening.
